(19) United States
(12) Patent Application Publication
(10) Pub. No.: US 2026/0231428 A1
(43) Pub. Date: Aug. 6, 2026

(54) SEMICONDUCTOR DEVICE INCLUDING GATE CONTACT PLUGS AND DATA STORAGE SYSTEM INCLUDING THE SAME

(71) Applicant: SAMSUNG ELECTRONICS CO., LTD., Suwon-si (KR)

(72) Inventors: Jeongyong Sung, Suwon-si (KR); Taekkyu Yoon, Suwon-si (KR); Sujin Go, Suwon-si (KR); Hyeongjin Kim, Suwon-si (KR); Dongsik Oh, Suwon-si (KR); Wooyong Jeon, Suwon-si (KR); Jeehoon Han, Suwon-si (KR)

(73) Assignee: SAMSUNG ELECTRONICS CO., LTD., Suwon-si (KR)

(21) Appl. No.: 19/529,751

(22) Filed: Feb. 4, 2026

(30) Foreign Application Priority Data
Feb. 4, 2025 (KR) 10-2025-0013606

(51) Int. Cl. H10B 43/40; G11C 5/06; H10B 43/10; H10B 43/27; H10B 43/35; H10D 30/01; H10D 30/69; H10D 62/17; H10W 20/41

(52) U.S. Cl. CPC H10B 43/40; G11C 5/063; H10B 43/10; H10B 43/27; H10B 43/35; H10D 30/693; H10D 62/292; H10W 20/435; H10D 30/0413

(57) ABSTRACT

A semiconductor device and a data storage system including the same are provided. The semiconductor device includes: a stack structure including gate electrodes and interlayer insulating layers; a vertical channel structure penetrating the stack structure; an insulating structure on the stack structure; gate contact plugs penetrating the insulating structure and extending downwardly and connected to the gate electrodes; and insulating spacers on side surfaces of the gate contact plugs, and the insulating structure includes intermediate insulating layer and a capping insulating layer on the intermediate insulating layer, a material of the capping insulating layer is different from a material of the insulating spacers, and a first gate contact plug of the gate contact plugs includes a first plug portion in contact with a first insulating spacer of the insulating spacers and a second plug portion in contact with the capping insulating layer.

### CROSS-REFERENCE TO RELATED APPLICATION(S)

This application is based on and claims priority to Korean Patent Application No. 10-2025-0013606 filed on Feb. 4, 2025, in the Korean Intellectual Property Office, the disclosure of which is incorporated herein by reference in its entirety.

### BACKGROUND

Example embodiments relate to a semiconductor device and a data storage system including the same.

In electronic systems requiring data storage, semiconductor devices capable of storing large amounts of data are required. Accordingly, methods of increasing data storage capacity of semiconductor devices are researched. For example, as one method of increasing the data storage capacity of semiconductor devices, a semiconductor device including memory cells arranged three-dimensionally instead of two-dimensionally is being proposed.

### SUMMARY

Example embodiments provide a semiconductor device that may increase a degree of integration.

Example embodiments provide a semiconductor device that may prevent electrical shorts from occurring between a gate contact plug and a gate electrode.

Example embodiments provide a data storage system including the semiconductor device.

According to an aspect of one or more example embodiments, a semiconductor device includes: a stack structure including gate electrodes and interlayer insulating layers alternately stacked in a vertical direction; a vertical channel structure penetrating through the stack structure and including a data storage layer; an insulating structure on the stack structure; gate contact plugs penetrating through the insulating structure and extending downwardly and connected to contact regions of the gate electrodes; and insulating spacers on side surfaces of the gate contact plugs, and the insulating structure includes at least one intermediate insulating layer on the stack structure and a capping insulating layer on the at least one intermediate insulating layer, a material of the capping insulating layer is different from a material of the insulating spacers, and a first gate contact plug of the gate contact plugs includes a first plug portion in contact with a first insulating spacer of the insulating spacers and a second plug portion in contact with the capping insulating layer.

According to an aspect of one or more example embodiments, a semiconductor device includes: a stack structure including gate electrodes and interlayer insulating layers alternately stacked in a vertical direction; a vertical channel structure penetrating through the stack structure and including a data storage layer; an insulating structure on the stack structure; and gate contact plugs penetrating through the insulating structure and extending downwardly and connected to contact regions of the gate electrodes, and the insulating structure includes at least one intermediate insulating layer on the stack structure and a capping insulating layer on the at least one intermediate insulating layer, the at least one intermediate insulating layer includes a material different from a material of the capping insulating layer, the capping insulating layer has an upper surface, coplanar with upper surfaces of the gate contact plugs, and a side surface of a first gate contact plug of the gate contact plugs, includes at least one bent portion at a higher level than an upper surface of an uppermost gate electrode of the gate electrodes.

According to an aspect of one or more example embodiments, a data storage system includes: a semiconductor device including an input/output pad; and a controller electrically connected to the semiconductor device through the input/output pad, and configured to control the semiconductor device, and the semiconductor device includes: a stack structure including gate electrodes and interlayer insulating layers alternately stacked in a vertical direction; a vertical channel structure penetrating through the stack structure and including a data storage layer; an insulating structure on the stack structure; gate contact plugs penetrating through the insulating structure and extending downwardly and connected to contact regions of the gate electrodes; and insulating spacers on side surfaces of the gate contact plugs, the insulating structure including at least one intermediate insulating layer on the stack structure and a capping insulating layer on the at least one intermediate insulating layer, a material of the capping insulating layer is different from a material of the insulating spacers, and a first gate contact plug of the gate contact plugs includes a first plug portion in contact with a first insulating spacer of the insulating spacers, and a second plug portion in contact with the capping insulating layer.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1, FIG. 2A, FIG. 2B, FIG. 3A, FIG. 3B and FIG. 4 are views illustrating a semiconductor device according to one or more example embodiments of the present disclosure;

FIG. 5A and FIG. 5B are partially enlarged cross-sectional views illustrating a semiconductor device according to one or more example embodiments of the present disclosure.

FIG. 6A and FIG. 6B are partially enlarged cross-sectional views illustrating a semiconductor device according to one or more example embodiments of the present disclosure;

FIG. 7, FIG. 8A and FIG. 8B are partial views illustrating a semiconductor device according to one or more example embodiments of the present disclosure;

FIG. 9A and FIG. 9B are partially enlarged cross-sectional views illustrating a semiconductor device according to one or more example embodiments of the present disclosure.

FIG. 10A and FIG. 10B are partially enlarged cross-sectional views illustrating a semiconductor device according to one or more example embodiments of the present disclosure;

FIG. 11A and FIG. 11B are partially enlarged cross-sectional views illustrating a semiconductor device according to one or more example embodiments of the present disclosure;

FIG. 12 is partially enlarged cross-sectional views illustrating a semiconductor device according to one or more example embodiments of the present disclosure;

FIG. 13 is a process flow diagram illustrating a semiconductor device manufacturing method according to one or more example embodiments of the present disclosure;

FIG. 14A, FIG. 14B, FIG. 15A, FIG. 15B, FIG. 16A, FIG. 16B, FIG. 17A, FIG. 17B, FIG. 18A, FIG. 18B, FIG. 19A, FIG. 19B, FIG. 20, FIG. 21, FIG. 22, FIG. 23 and FIG. 24 are views illustrating examples of a semiconductor device manufacturing method according to one or more example embodiments of the present disclosure;

FIG. 25 is a perspective view schematically illustrating a data storage system including a semiconductor device according to one or more example embodiments of the present disclosure; and

FIG. 26 is a cross-sectional view schematically illustrating a data storage system including a semiconductor device according to one or more example embodiments of the present disclosure.

### DETAILED DESCRIPTION

Hereinafter, example embodiments will be described with reference to the accompanying drawings.

Terms such as “upper,” “intermediate,” “lower,” “inner” and “outer” may be replaced with other terms, such as “first,” “second” and “third,” to describe components of the specification. Although terms such as “first,” “second,” and “third” may be used to describe various elements, the elements are not limited by the terms, and the “first element” may be named the “second element,” or may be named other terms that may be distinguished from other elements. The size ratio, width ratio, length ratio, and the like, between elements depicted in the drawings may be understood from the elements depicted in the drawings even without separate explanation.

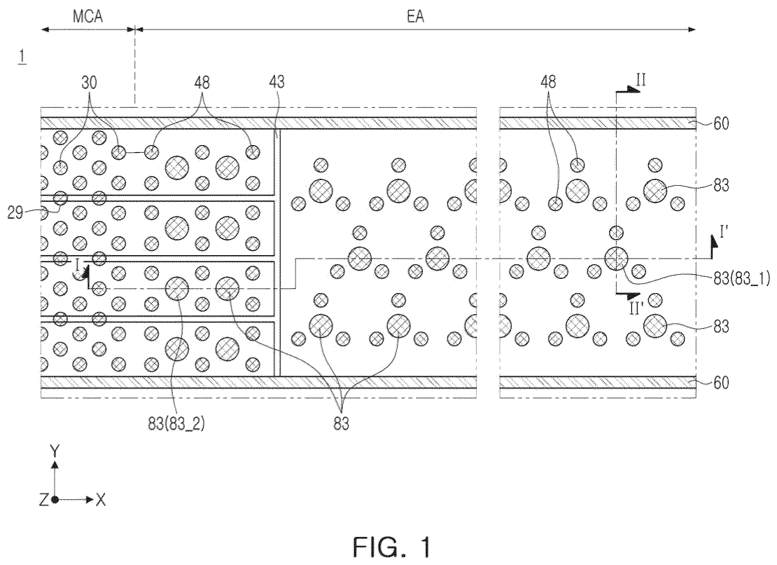

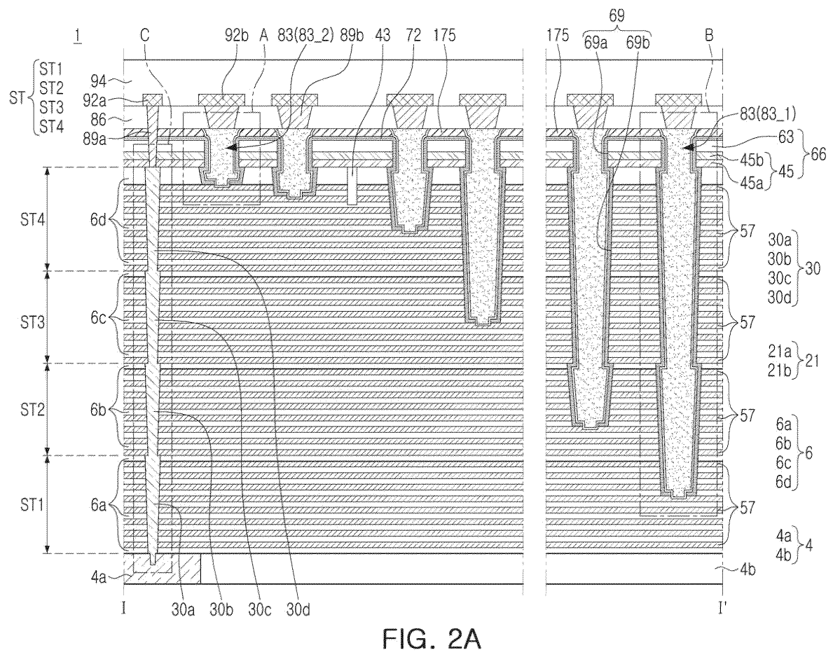

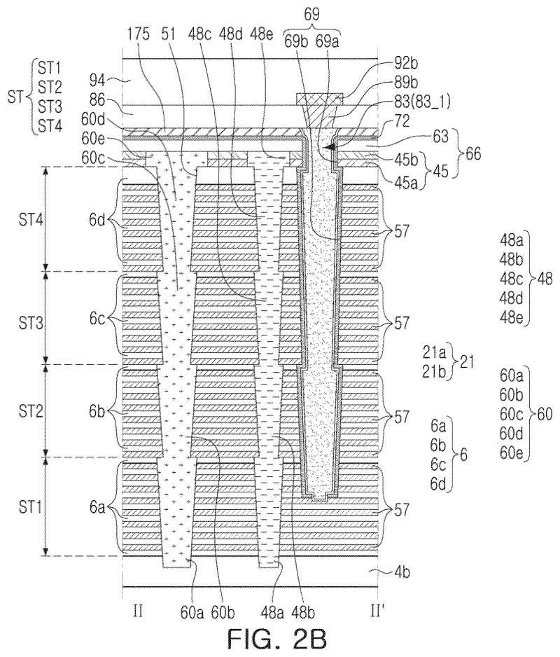

FIG. 1, FIG. 2A, FIG. 2B, FIG. 3A, FIG. 3B and FIG. 4 are views illustrating a semiconductor device according to one or more example embodiments of the present disclosure. FIG. 1 is a plan view illustrating an example of a semiconductor device according to one or more example embodiments of the present disclosure, FIG. 2A is a cross-sectional view illustrating a region taken along line I-I′ of FIG. 1, FIG. 2B is a cross-sectional view illustrating a region taken along line II-II′ of FIG. 1, FIG. 3A is an enlarged partial view of a portion indicated by ‘A’ of FIG. 2A, FIG. 3B is a partially enlarged view of a portion indicated by ‘B’ of FIG. 2A, and FIG. 4 is a partially enlarged view of a portion indicated by ‘C’ of FIG. 2A.

Referring to FIGS. 1, 2A, 2B, 3A, 3B and 4, a semiconductor device 1 according to an example embodiment may include a stack structure ST, a vertical channel structure 30, an insulating structure INS, gate contact plugs 83, and insulating spacers 72.

The stack structure ST may include a first stacked portion ST1, a second stacked portion ST2, a third stacked portion ST3, and a fourth stacked portion ST4, which are sequentially stacked in a vertical direction (Z-direction). Each of the first to fourth stacked portions ST1, ST2, ST3 and ST4 may include interlayer insulating layers 6 and gate electrodes 57. In the first to fourth stacked portions ST1, ST2, ST3 and ST4, the interlayer insulating layers 6 of the first stacked portion ST1 may be referred to as first interlayer insulating layers 6a, the interlayer insulating layers 6 of the second stacked portion ST2 may be referred to as second interlayer insulating layers 6b, the interlayer insulating layers 6 of the third stacked portion ST3 may be referred to as third interlayer insulating layers 6c, and the interlayer insulating layers 6 of the fourth stacked portion ST4 may be referred to as fourth interlayer insulating layers 6d. Accordingly, the stack structure ST may include the interlayer insulating layers 6 and the gate electrodes 57 alternately stacked in the vertical direction (Z-direction).

Among the interlayer insulating layers 6 and the gate electrodes 57 of the stack structure ST, a lowermost layer may be an interlayer insulating layer in a lowermost portion, among the interlayer insulating layers 6, and an uppermost layer may be an interlayer insulating layer in an uppermost portion, among the interlayer insulating layers 6. A thickness of the interlayer insulating layer in the uppermost portion, among the interlayer insulating layers 6, may be greater than a thicknesses of each of remaining interlayer insulating layers.

The stack structure ST may further include gate dielectric layers 54 covering an upper surface and a lower surface of each of the gate electrodes 57 and covering a side surface of a portion of each of the gate electrodes 57.

The stack structure ST may include an area disposed within a memory cell array area MCA and an area disposed within a connection area EA adjacent to the memory cell array area MCA in a first horizontal direction (X-direction), perpendicular to the vertical direction (Z-direction).

In an example embodiment, lower gate electrodes disposed in lower portions of the gate electrodes 57 in the first stacked portion ST1 may include a lower selection gate electrode and a lower erase control gate electrode.

In an example embodiment, among the gate electrodes 57 in the fourth stacked portion ST4, upper gate electrodes disposed in the memory cell array area MCA and a portion of which extend into the connection area EA may include an upper selection gate electrode and an upper erase control gate electrode.

In an example embodiment, the gate electrodes disposed between the lower gate electrodes and the upper gate electrodes, among the gate electrodes 57, may be word lines.

The semiconductor device 1 may further include an insulating pattern 43 penetrating through the upper gate electrodes, among the gate electrodes 57, in the fourth stacked portion ST4 and disposed at a higher level than the gate electrodes that may be word lines.

The semiconductor device 1 may further include a pattern structure 4 below the stack structure ST. The pattern structure 4 may include a first pattern structure 4a arranged in the memory cell array area MCA and a second pattern structure 4b disposed in the connection area EA. The first pattern structure 4a may include at least one of doped silicon or a metallic material having a first conductivity type. The second pattern structure 4b may include an insulating material.

The vertical channel structure 30 may penetrate through the stack structure ST within the memory cell array area MCA. The vertical channel structure 30 (see FIG. 4) may include a first vertical channel portion 30a penetrating through the first stacked portion ST1, a second vertical channel portion 30b penetrating through the second stacked portion ST2, a third vertical channel portion 30c penetrating through the third stacked portion ST3, and a fourth vertical channel portion 30d penetrating through the fourth stacked portion ST4.

A side surface of the vertical channel structure 30 may include a first bonded portion 30B1 between a side surface of the first vertical channel portion 30a and a side surface of the second vertical channel portion 30b, a second bonded portion 30B2 between a side surface of the second vertical channel portion 30b and a side surface of the third vertical channel portion 30c, and a third bonded portion 30B3 between a side surface of the third vertical channel portion 30c and a side surface of the fourth vertical channel portion 30d.

Each of the first to third bonded portions 30B1, 30B2 and 30B3 may be formed by bending from a side surface disposed relatively therebelow and a side surface disposed relatively thereabove. Each of the first to third bonded portions 30B1, 30B2 and 30B3 may also be referred to as a bent portion.

The vertical channel structure 30 (see FIG. 4) may include an insulating core region 39, a channel layer 36, a data storage structure 33, and a pad pattern 42.

The channel layer 36 may be disposed on a side surface of at least the insulating core region 39 and may be connected to the first pattern structure 4a. The channel layer 36 may extend between a lower surface of the insulating core region 39 and the first pattern structure 4a. The data storage structure 33 may be disposed on an outer surface of the channel layer 36. The pad pattern 42 may be disposed on the insulating core region 39 and may be connected to the channel layer 36.

The insulating core region 39 may include an insulating material such as a silicon oxide. The channel layer 36 may include a semiconductor material such as polysilicon, single crystal silicon, or an oxide semiconductor. A portion of the first pattern structure 4a in contact with the channel layer 36 may include at least doped silicon. For example, the first pattern structure 4a may include polysilicon having N-type conductivity. According to an example embodiment, the first pattern structure 4a may include polysilicon having N-type conductivity and polysilicon having P-type conductivity.

The data storage structure 33 may include a first dielectric layer 33a, a second dielectric layer 33c, and a data storage layer 33b between the first and second dielectric layers 33a and 33c. The second dielectric layer 33c may be in contact with the channel layer 36. The first dielectric layer 33a may be a blocking dielectric layer. The first dielectric layer 33a may include at least one of silicon oxide or a high-κ dielectric. The second dielectric layer 33c may be a tunneling dielectric layer. The second dielectric layer 33c may include silicon oxide or silicon oxide doped with impurities. The data storage layer 33b may include a material capable of storing data by trapping a charge, and may include, for example, a silicon nitride. The data storage layer 33b may include regions capable of storing data in a semiconductor device such as a flash memory device. The pad pattern 42 may include doped polysilicon.

In an example embodiment, the data storage structure 33 may include the data storage layer 33b capable of storing data by trapping a charge, but the example embodiment is not limited thereto. For example, the data storage structure 33 may include data storage regions used in a ferroelectric memory capable of storing data by utilizing remnant polarization by a dipole.

The semiconductor device 1 may further include a dummy vertical channel structure 29 (see FIG. 1) that may vertically overlap the insulating pattern 43 and may be formed to have the same structure as the vertical channel structure 30.

The insulating structure INS may be disposed on the stack structure ST. The insulating structure INS may include at least one intermediate insulating layer 66 arranged on the stack structure ST and a capping insulating layer 175 on the at least one intermediate insulating layer 66.

The at least one intermediate insulating layer 66 may include a material different from the material of the capping insulating layer 175. For example, the capping insulating layer 175 may include a nitride-based insulating material (e.g., at least one of SiN, SiBN, SiCN, SiOCN or SiON), and the at least one intermediate insulating layer 66 may include an oxide-based insulating material (e.g., silicon oxide, or the like).

The at least one intermediate insulating layer 66 may include a first intermediate insulating layer 45 and a second intermediate insulating layer 63 on the first intermediate insulating layer 45.

In one example, the first intermediate insulating layer 45 may be formed of a single material. For example, the first intermediate insulating layer 45 may be formed of an oxide-based insulating material (e.g., silicon oxide, or the like) or a nitride-based insulating material (e.g., at least one of SiN, SiBN, SiCN, SiOCN or SiON).

In one example, the first intermediate insulating layer 45 may include a first-first intermediate insulating layer 45a and a first-second intermediate insulating layer 45b on the first-first intermediate insulating layer 45a. The first-first intermediate insulating layer 45a may be formed of a nitride-based insulating material (e.g., at least one of SiN, SiBN, SiCN, SiOCN or SiON), and the first-second intermediate insulating layer 45b may be formed of a nitride-based insulating material (e.g., at least one of SiN, SiBN, SiCN, SiOCN or SiON).

The second intermediate insulating layer 63 may include an oxide-based insulating material (e.g., silicon oxide, etc.).

A material of the capping insulating layer 175 may be different from a material of the interlayer insulating layers 6. For example, the capping insulating layer 175 may include a nitride-based insulating material (e.g., at least one of SiN, SiBN, SiCN, SiOCN or SiON), and the interlayer insulating layers 6 may include an oxide-based insulating material (e.g., silicon oxide, or the like).

The semiconductor device 1 may further include a vertical support structure 48 penetrating through the stack structure ST.

The vertical support structure 48 may not include a material of the channel layer 36 of the vertical channel structure 30. The vertical support structure 48 may be formed of an oxide-based insulating material (e.g., silicon oxide, or the like).

The vertical support structure 48 may include a first vertical supporter portion 48a penetrating through the first stacked portion ST1, a second vertical supporter portion 48b penetrating through the second stacked portion ST2, a third vertical supporter portion 48c penetrating through the third stacked portion ST3, and a fourth vertical supporter portion 48d penetrating through the fourth stacked portion ST4.

The vertical support structure 48 may further include a fifth vertical supporter portion 48e extending upwardly from the fourth vertical supporter portion 48d and penetrating through the first intermediate insulating layer 45. A width of the fifth vertical supporter portion 48e may be greater than a width of the fourth vertical supporter portion 48d adjacent to the fifth vertical supporter portion 48e.

The semiconductor device 1 may further include separation structures 60 penetrating through the stack structure ST. Each of the separation structures 60 may extend in the first horizontal direction (X-direction), and the separation structures 60 may be parallel to each other in a second horizontal direction (Y-direction), perpendicular to the first horizontal direction (X-direction).

In one example, each of the separation structures 60 may be formed of an insulating material.

In one example, each of the separation structures 60 may include a conductive pattern and an insulating spacer on a side surface of the conductive pattern.

Each of the above separation structures 60 may include a first vertical separation portion 60a penetrating through the first stacked portion ST1, a second vertical separation portion 60b penetrating through the second stacked portion ST2, a third vertical separation portion 60c penetrating through the third stacked portion ST3, and a fourth vertical separation portion 60d penetrating through the fourth stacked portion ST4.

Each of the separation structures 60 may further include a fifth vertical separation portion 60e extending upwardly from the fourth vertical separation portion 60d and penetrating through the first intermediate insulating layer 45. A width of the fifth vertical separation portion 60e may be greater than a width of the fourth vertical separation portion 60d adjacent to the fifth vertical separation portion 60e.

The gate contact plugs 83 may be disposed within contact holes 69. Each of the contact holes 69 may include an upper contact hole 69a penetrating through the insulating structure INS and a lower contact hole 69b extending from the upper contact hole 69a into the stack structure ST.

In one example, a width of each of the upper contact holes 69a may be less than width of each of the lower contact holes 69b.

In one example, the capping insulating layer 175 may not vertically overlap the upper contact holes 69a. The gate contact plugs 83 may extend downwardly by penetrating through the insulating structure INS and may be connected to contact regions 57c of the gate electrodes 57. The capping insulating layer 175 may have an upper surface, coplanar with upper surfaces of the gate contact plugs 83.

The insulating spacers 72 may be disposed on side surfaces of the gate contact plugs 83.

In one example, the insulating spacers 72 may include first spacer portions 72a disposed on the side surfaces of the gate contact plugs 83 and second spacer portions 72b extending from the first spacer portions 72a and disposed between the at least one intermediate insulating layer 66 and the capping insulating layer 175. The second spacer portions 72b may extend from the first spacer portions 72a and may be disposed between an upper surface of the second intermediate insulating layer 63 and a lower surface of the capping insulating layer 175.

Upper surfaces of the insulating spacers 72 may be disposed at a lower level than upper surfaces of the gate contact plugs 83.

A material of the capping insulating layer 175 may be different from a material of the insulating spacers 72. For example, the capping insulating layer 175 may include a nitride-based insulating material (e.g., at least one of SiN, SiBN, SiCN, SiOCN or SiON), and the insulating spacers 72 may include an oxide-based insulating material (e.g., silicon oxide, or the like).

In one example, each of the gate contact plugs 83 may include a plug material pattern 80 and a conductive liner 78 covering a side surface and a lower surface of the plug pattern 80. The gate contact plugs 83 may extend continuously from an upper surface thereof to a lower surface thereof, which contacts the contact regions 57c of the gate electrodes 57. The conductive liner 78 may include a first conductive material (e.g., at least one of TiN, TaN, WN, NbN, TiAl, TiAlN, TiSi, TiSiN, TaSiN or RuTiN), and the plug pattern 80 may include a second conductive material (e.g., at least one of Ti, Ta, Ru, W, Mo, Pt, Ni or Co) different from the first conductive material.

In one example, each of the gate contact plugs 83 may be formed of a single material (e.g., TiN, TaN, WN, NbN, TiAl, TiAlN, TiSi, TiSiN, TaSiN, RuTiN, Ti, Ta, Ru, W, Mo, Pt, Ni, or Co, or the like).

The gate contact plugs 83 may include a first gate contact plug 83_1 connected to a first contact region 57c_1 of a first gate electrode 57_1, among the gate electrodes 57, and a second gate contact plug 83_2 connected to a second contact region 57c_2 of a second gate electrode 57_2, among the gate electrodes 57.

In one example, the first gate electrode 57_1 may be a gate electrode positioned within the first stacked portion ST1, among the gate electrodes 57.

In one example, the second gate electrode 57_2 may be an uppermost gate electrode, among the gate electrodes 57.

The insulating spacers 72 may include a first insulating spacer 72_1 on a side surface of the first gate contact plug 83_1. The first insulating spacer 72_1 may include the first spacer portion 72a disposed on the side surface of the first gate contact plug 83_1 and the second spacer portion 72b extending from the first spacer portion 72a to between the upper surface of the second intermediate insulating layer 63 and the lower surface of the capping insulating layer 175.

Each of the gate contact plugs 83 may have a stepped lower surface. For example, a lower surface of each of the gate contact plugs 83 may include a first portion in contact with the insulating spacer 72 and a second portion disposed at a lower level than the insulating spacer 72 and in contact with a gate contact region 54c. For example, in the gate contact plug 83 and the insulating spacer 72 in contact with each other, the insulating spacer 72 may cover a side surface of the gate contact plug 83 and may extend to cover the first portion of the lower surface of the gate contact plug 83.

The first gate contact plug 83_1 may include a first plug portion 83_P1 in contact with the first insulating spacer 72_1 and a second plug portion 83_P2 in contact with the capping insulating layer 175.

According to example embodiments, a structure including the gate contact plugs 83, the insulating spacers 72, and the capping insulating layer 175 may prevent an electrical short between the side surfaces of the gate contact plugs 83 and side surfaces of the gate electrodes 57.

The first gate contact plug 83_1 may include a lower region 83a connected to the first contact region 57c_1 of the first gate electrode 57_1 in the first stacked portion ST1 and extending upwardly and penetrating through the second stacked portion ST2, a first upper region 83b extending upwardly from the lower region 83a and penetrating through the third stacked portion ST3 and the fourth stacked portion ST4, a second upper region 83c extending upwardly from the first upper region 83b, and a third upper region 83d extending upwardly from the second upper region 83c.

The side surface of the first gate contact plug 83_1 may include a first bonded portion 83LB (see FIG. 3B) between a side surface of the lower region 83a and a side surface of the first upper region 83b, a second bonded portion 83UBa (see FIG. 3A) between the side surface of the first upper region 83b and a side surface of the second upper region 83c, and a third bonded portion 83UBb (see FIG. 3A) between the side surface of the second upper region 83c and a side surface of the third upper region 83d.

In example embodiments, each of the first to third bonded portions 83LB, 83UBa and 83UBb may be formed by bending from a side surface disposed relatively therebelow and a side surface disposed relatively thereabove. Each of the first to third bonded portions 83LB, 83UBa and 83UBb may also be referred to as a bent portion. Hereinafter, the first to third bonded portions 83LB, 83UBa and 83UBb are referred to as first to third bending portions 83LB, 83UBa and 83UBb, respectively.

The side surface of the first gate contact plug 83_1 may include at least one bending portion 83UBa or 83UBb at a higher level than an upper surface of the uppermost gate electrode 57_2. For example, the side surface of the first gate contact plug 83_1 may include the second and third bending portions 83UBa and 83UBb disposed on different levels at a higher level than the upper surface of the uppermost gate electrode 57_2. For example, the side surface of the first gate contact plug 83_1 may include the second bent portion 83UBa disposed at a higher level than the upper surface of the uppermost gate electrode 57_2 and the third bent portion disposed at a higher level than that of the second bent portion 83UBa.

In the first gate contact plug 83_1, at least a portion of the first upper region 83b may be disposed at a higher level than the uppermost gate electrode 57_2, among the gate electrodes 57.

In the first gate contact plug 83_1, the second upper region 83c may have a width different from a width of the first upper region 83b on the first upper region 83b.

In the first gate contact plug 83_1, the third upper region 83d may have a width different from a width of the second upper region 83c on the second upper region 83c.

In the first gate contact plug 83_1, the width of the first upper region 83b adjacent to the second upper region 83c may be greater than the width of the second upper region 83c adjacent to the first upper region 83b.

In the first gate contact plug 83_1, a width of an upper surface of the third upper region 83d may be greater than a width of a middle portion of the second upper region 83c between the first upper region 83b and the third upper region 83d.

In the first gate contact plug 83_1, the third upper region 83d may have a width that decreases downwardly from an upper surface thereof.

The semiconductor device 1 may further include an upper insulating layer 86 on the capping insulating layer 175. The upper insulating layer 86 may include an oxide-based insulating material (e.g., silicon oxide, or the like).

The semiconductor device 1 may further include a bit line stud 89a penetrating through the upper insulating layer 86 and the insulating structure INS and connected to the vertical channel structure 30.

The semiconductor device 1 may further include gate studs 89b penetrating through the upper insulating layer 86 and connected to the gate contact plugs 83.

The semiconductor device 1 may further include a bit line 92a connected to the bit line stud 89a, and gate interconnection lines 92b connected to the gate studs 89b. The bit line 92a and the gate interconnection lines 92b may be disposed on the upper insulating layer 86. The bit line 92a may be disposed at the same level as the gate interconnection lines 92b.

The semiconductor device 1 may further include an upper insulating structure 94 covering the bit line 92a and the gate interconnection lines 92b on the upper insulating layer 86.

Next, various examples of modifications of the elements of the above-described example embodiment will be described. The various examples of modifications of the elements of the above-described embodiment described below will be described with a focus on modified or replaced elements. Here, the elements described above may be directly cited without a separate detailed description, or the description thereof may be omitted. In addition, the elements described below that may be modified or replaced are described with reference to the drawings below, but the elements that may be modified or replaced may be combined with each other or with the elements described above to form the semiconductor device 1 according to an example embodiment of the present disclosure.

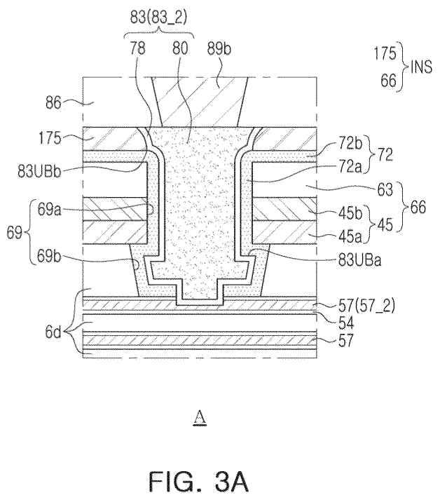

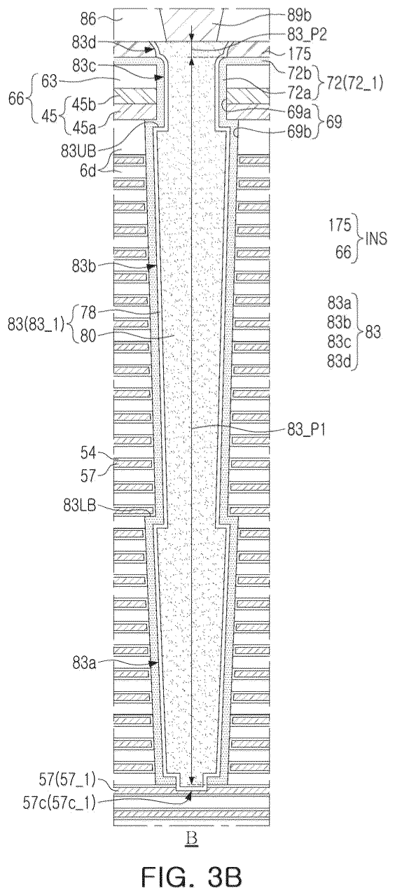

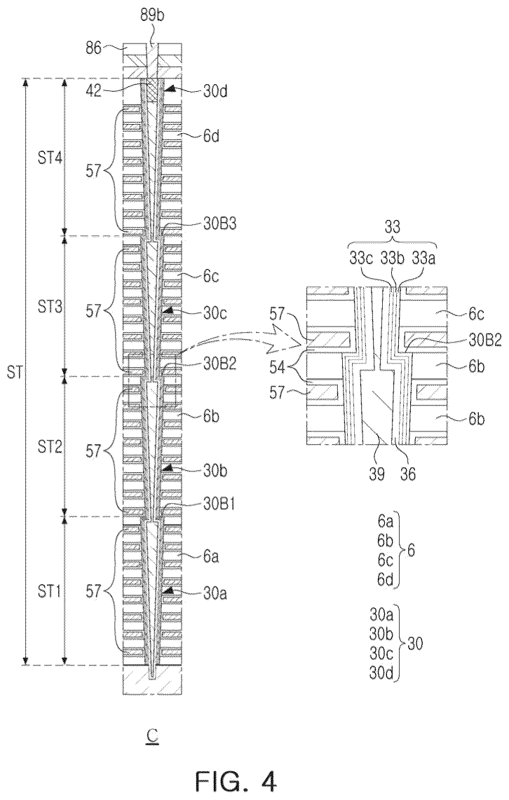

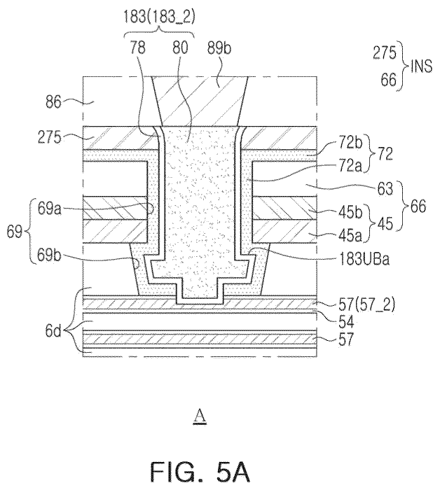

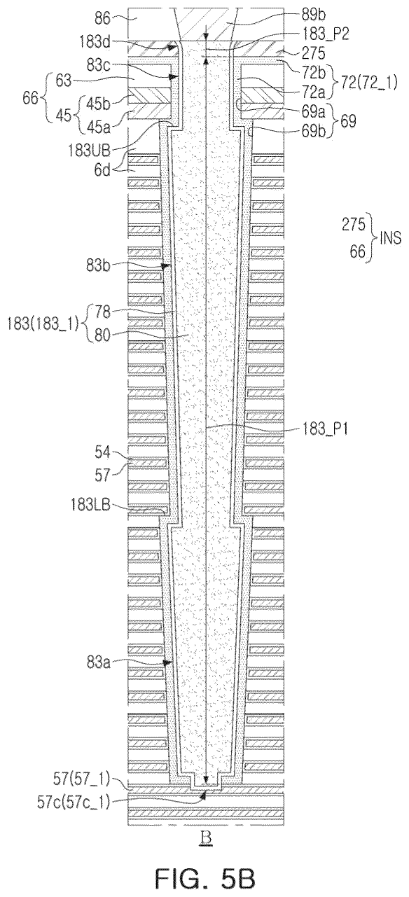

FIGS. 5A and 5B are partially enlarged cross-sectional views illustrating examples of the capping insulating layer 175 (see FIGS. 3A and 3B) and the gate contact plugs 83 (see FIGS. 3A and 3B) described above. FIG. 5A is a partially enlarged cross-sectional view corresponding to FIG. 3A, and FIG. 5B is a partially enlarged cross-sectional view corresponding to FIG. 3B.

In one or more example embodiments, referring to FIGS. 5A and 5B, the capping insulating layer 175 (see FIGS. 3A and 3B) described above may be replaced with a capping insulating layer 275 having a side surface extending from a side surface of the first spacer portion 72a. The capping insulating layer 275 may vertically overlap the first spacer portion 72a.

The gate contact plugs 83 (see FIGS. 3A and 3B) including the first and second gate contact plugs 83_1 and 83_2 described above may be replaced with gate contact plugs 183 including first and second gate contact plugs 183_1 and 183_2 as in FIGS. 5A and 5B.

The first gate contact plug 183_1 may include a first plug portion 183_P1 in contact with the first insulating spacer 72_1 and a second plug portion 183_P2 in contact with the capping insulating layer 275.

The first gate contact plug 183_1 may include a first upper region 83b, which is disposed on a lower region 83a and at least a portion of which is disposed at a higher level than the uppermost gate electrode 57_2, among the gate electrodes 57, a second upper region 83c disposed on the first upper region 83b and having a width different from a width of the first upper region 83b, and a third upper region 183d disposed on the second upper region 83c and disposed at the same level as the capping insulating layer 275.

A side surface of the first gate contact plug 183_1 may include a first bent portion 183 LB and a second bent portion 183UBa corresponding to the first bent portion 83LB and the second bent portion 83UBa described above, respectively.

A difference between a width of an upper surface of the third upper region 183d and a width of the third upper region 183d adjacent to the second upper region 83c may be greater than a difference between the width of the second upper region 83c adjacent to the first upper region 83b and the width of the second upper region 83c adjacent to the third upper region 183d.

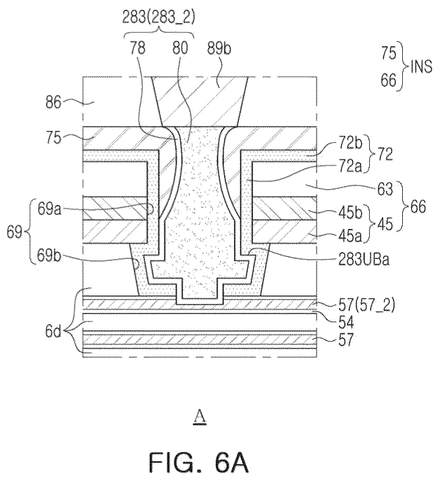

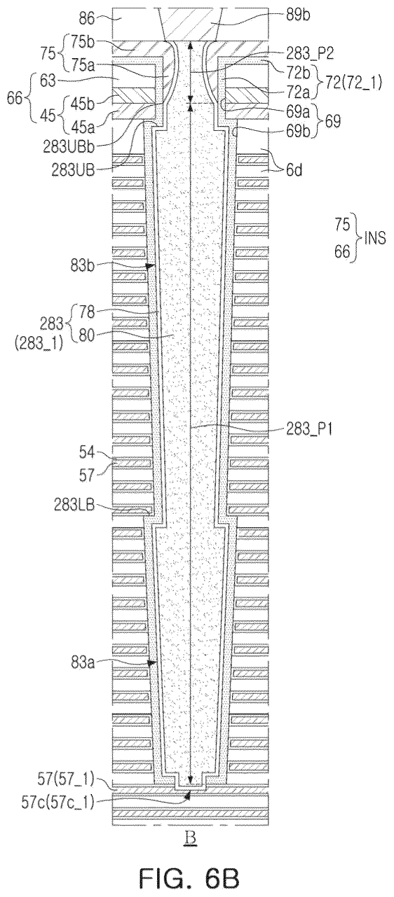

FIGS. 6A and 6B are partially enlarged cross-sectional views illustrating examples of the capping insulating layer 175 (see FIGS. 3A and 3B) and the gate contact plugs 83 (see FIGS. 3A and 3B) described above. FIG. 6A is a partially enlarged cross-sectional view corresponding to FIG. 6A, and FIG. 6B is a partially enlarged cross-sectional view corresponding to FIG. 3B.

In one or more example embodiments, referring to FIGS. 6A and 6B, the gate contact plugs 83 (see FIGS. 3A and 3B) including the first and second gate contact plugs 83_1 and 83_2 described above may be replaced with gate contact plugs 283 including first and second gate contact plugs 283_1 and 283_2 as in FIGS. 6A and 6B.

The capping insulating layer 175 (see FIGS. 3A and 3B) described above may be replaced with a capping insulating layer 75 including extension portions 75a extending from a portion covering an upper surface of the at least one intermediate insulating layer 66 to a space between side surfaces of the gate contact plugs 283 and the at least one intermediate insulating layer 66.

The capping insulating layer 75 may include a capping portion 75b disposed on the second spacer portion 72b of the insulating spacers 72 (or the first insulating spacer 72_1) on the upper surface of the at least one intermediate insulating layer 66 and the extension portions 75a extending from the capping portion 75b. The extension portions 75a may extend from the capping portion 75b to between the first spacer portions 72a and the gate contact plugs 283.

The first gate contact plug 283_1 may include a first plug portion 283_P1 in contact with the first insulating spacer 72_1 and a second plug portion 283_P2 in contact with the capping insulating layer 75.

Lower ends of the extension portions 75a of the capping insulating layer 75 may be disposed at a lower level than the upper surface of the at least one intermediate insulating layer 66.

The extension portion 75a of the capping insulating layer 75 in contact with the first gate contact plug 283_1 may be disposed at a higher level than the uppermost gate electrode 57_2, among the gate electrodes 57.

In the first gate contact plug 283_1, an upper end of the first plug portion 283_P1 in contact with the first insulating spacer 72_1 and a lower end of the second plug portion 283_P2 in contact with the capping insulating layer 75 may be disposed at a higher level than the uppermost gate electrode 57_2, among the gate electrodes 57.

A side surface of the first gate contact plug 283_1 may include a first bent portion 283LB and a second bent portion 283UBa corresponding to the first bent portion 83LB and the second bent portion 83UBa described above, respectively. The side surface of the first gate contact plug 283_1 may further include a third bent portion 283Ub in contact with a lower end of the extension portion 75a of the capping insulating layer 75.

The first gate contact plug 283_1 may have a concave side surface in a direction observed from a vertical center axis of the first gate contact plug 283_1, at the same level as the capping insulating layer 75.

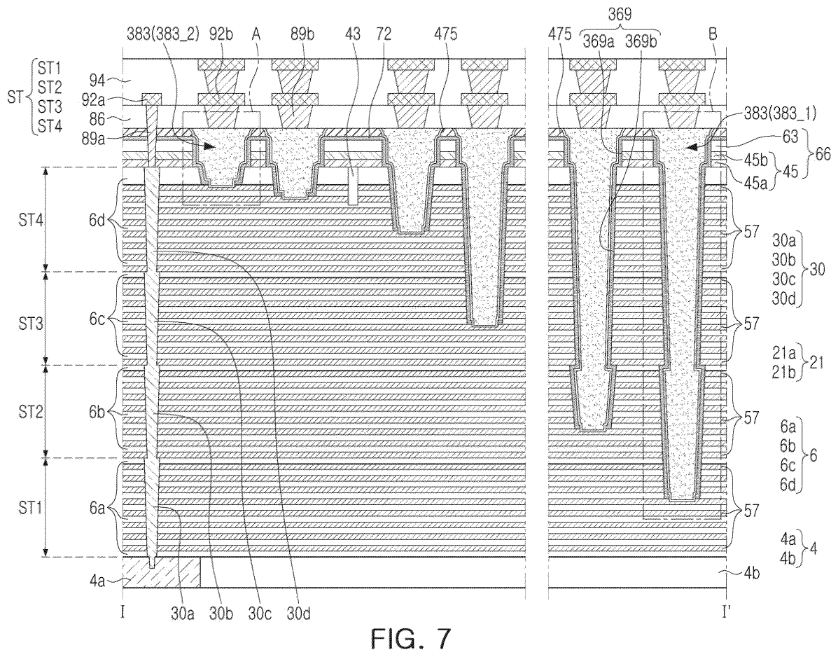

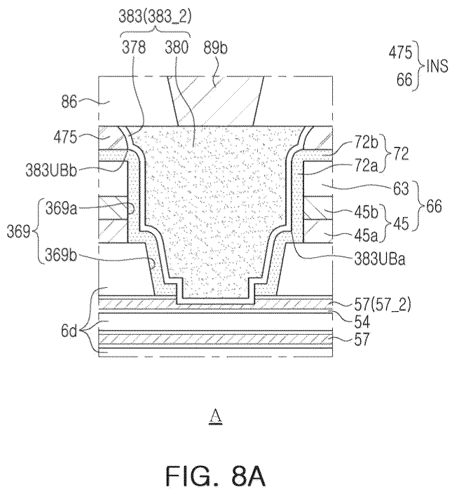

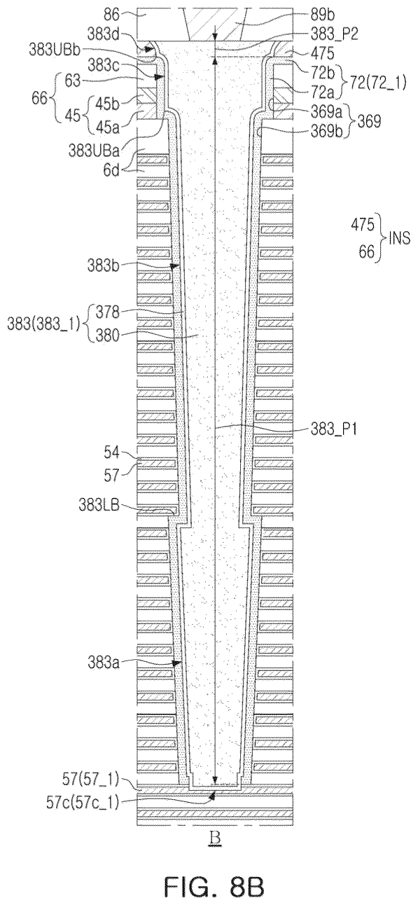

FIGS. 7, 8A and 8B are partially enlarged views illustrating examples of the capping insulating layer 175 (see FIGS. 2A, 2B, 3A and 3B), the gate contact plugs 83 (see FIGS. 2A, 2B, 3A and 3B), and the contact holes 69 (see FIGS. 2A, 2B, 3A and 3B) described above. FIG. 7 is a cross-sectional view illustrating an area taken along line I-I′ of FIG. 1 and a cross-sectional view corresponding to the cross-sectional view of FIG. 2A, FIG. 8A is a partially enlarged cross-sectional view corresponding to FIG. 3A, and FIG. 8B is a partially enlarged cross-sectional view corresponding to FIG. 3B.

In one or more example embodiments, referring to FIGS. 7, 8A and 8B, each of the contact holes 69 (see FIGS. 2A, 2B, 3A and 3B) including the lower contact hole 69b and the upper contact hole 69a described above may be replaced with contact holes 369 respectively including a lower contact hole 369b and an upper contact hole 369a as in FIGS. 7, 8A and 8B.

The upper contact hole 369a may penetrate through the insulating structure INS. The lower contact hole 369b may extend from the upper contact hole 69a into the stack structure ST.

In one example, a width of each of the upper contact holes 369a may be greater than a width of each of the lower contact holes 369b.

The capping insulating layer 175 (see FIGS. 2A, 2B, 3A and 3B) described above may be replaced with a capping insulating layer 475 that does not vertically overlap the upper contact holes 369a.

The gate contact plugs 83 (see FIGS. 3A and 3B) including the first and second gate contact plugs 83_1 and 83_2 described above may be replaced with gate contact plugs 383 including the first and second gate contact plugs 383_1 and 383_2 as in FIGS. 7, 8A and 8B.

In one example, each of the gate contact plugs 383 may include a plug material pattern 380 and a conductive liner 378 covering a side surface and a bottom surface of the plug pattern 380.

The first gate contact plug 383_1 may include a first plug portion 383_P1 in contact with the first insulating spacer 72_1 and a second plug portion 383_P2 in contact with the capping insulating layer 475.

The first gate contact plug 383_1 may include a lower region 383a connected to the first contact region 57c_1 of the first gate electrode 57_1 in the first stacked portion ST1 and extending upwardly and penetrates through the second stacked portion ST2, a first upper region 383b extending upwardly from the lower region 383a and penetrating through the third stacked portion ST3 and the fourth stacked portion ST4, a second upper region 383c extending upwardly from the first upper region 383b, and a third upper region 383d extending upwardly from the second upper region 383c.

A side surface of the first gate contact plug 383_1 may include a first bent portion 383LB between a side surface of the lower region 383a and a side surface of the first upper region 383b, a second bent portion 383UBa between the side surface of the first upper region 383b and a side surface of the second upper region 383c, and a third bent portion 383UBb between the side surface of the second upper region 383c and a side surface of the third upper region 383d.

The side surface of the first gate contact plug 383_1 may include at least one bent portion 383UBa or 383UBb at a higher level than an upper surface of the uppermost gate electrode 57_1. For example, the side surface of the first gate contact plug 383_1 may include the second and third bent portions 383UBa and 383UBb disposed on different levels higher than that of the upper surface of the uppermost gate electrode 57_1. For example, the side surface of the first gate contact plug 383_1 may include the second bent portion 383UBa disposed at a higher level than the upper surface of the uppermost gate electrode 57_1 and the third bent portion 83UBb disposed at a higher level than the second bent portion 383UBa.

As described above, the first gate contact plug 383_1 may include the first upper region 383b, at least a portion of which is disposed at a higher level than the upper surface of the uppermost gate electrode 57_1, the second upper region 383c disposed on the first upper region 383b and having a width greater than a width of the first upper region 383b, and the third upper region 383d disposed on the second upper region 383b and having a width greater than a width of the second upper region 383b.

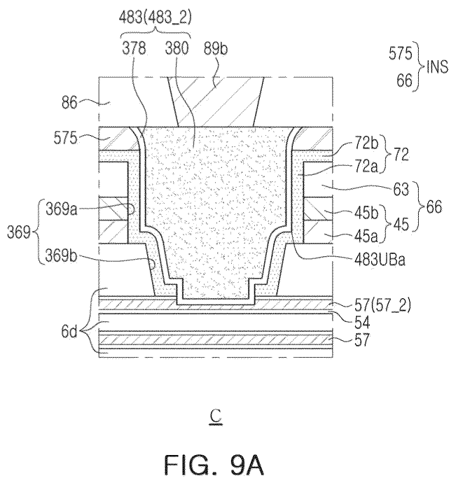

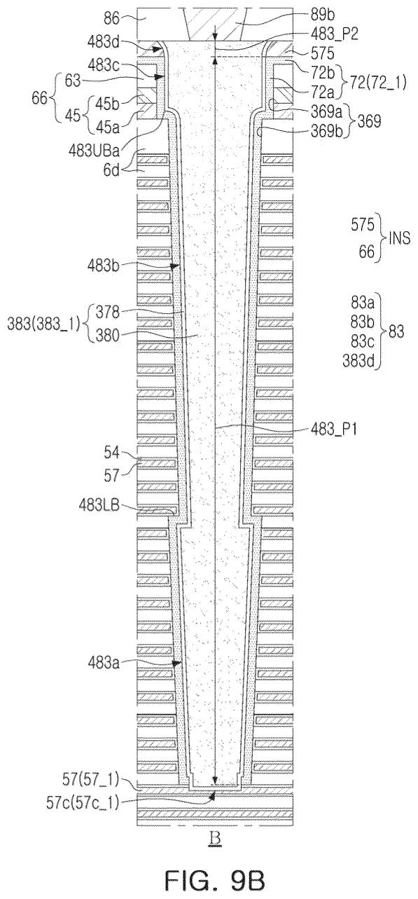

FIGS. 9A and 9B are partially enlarged cross-sectional views illustrating examples of the capping insulating layer 475 (see FIGS. 8A and 8B) and the gate contact plugs 383 (see FIGS. 8A and 8B) described above. FIG. 9A is a partially enlarged cross-sectional view corresponding to FIG. 8A, and FIG. 9B is a partially enlarged cross-sectional view corresponding to FIG. 8B.

In one or more example embodiments, referring to FIGS. 9A and 9B, the capping insulation layer 475 (see FIGS. 8A and 8B) described above may be replaced with a capping insulation layer 575 having a side surface extending from the side surface of the first spacer portion 72a. The capping insulation layer 575 may vertically overlap the first spacer portion 72a.

The gate contact plugs 383 (see FIGS. 8A and 8B) including the first and second gate contact plugs 383_1 and 383_2 described above may be replaced with gate contact plugs 483 including first and second gate contact plugs 483_1 and 483_2 as in FIGS. 9A and 9B.

The first gate contact plug 483_1 may include a first plug portion 483_P1 in contact with the first insulating spacer 72_1 and a second plug portion 483_P2 in contact with the capping insulating layer 575.

The first gate contact plug 483_1 may include a first upper region 483b, which is disposed on a lower region 483a and at least a portion of which is disposed at a higher level than the uppermost gate electrode 57_2 among the gate electrodes 57, a second upper region 483c disposed on the first upper region 483b and having a width different from a width of the first upper region 483b, and a third upper region 483d disposed on the second upper region 483c and disposed at the same level as the capping insulating layer 575.

A side surface of the first gate contact plug 483_1 may include a first bent portion 483LB and a second bent portion 483UBa corresponding to the first bent portion 383LB and the second bent portion 383UBa described above, respectively.

A difference between a width of an upper surface of the third upper region 483d and a width of the third upper region 483d adjacent to the second upper region 483c may be greater than a difference between a width of the second upper region 483c adjacent to the first upper region 483b and a width of the second upper region 483c adjacent to the third upper region 483d.

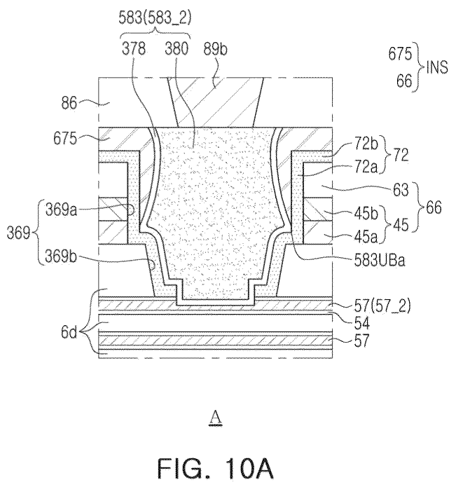

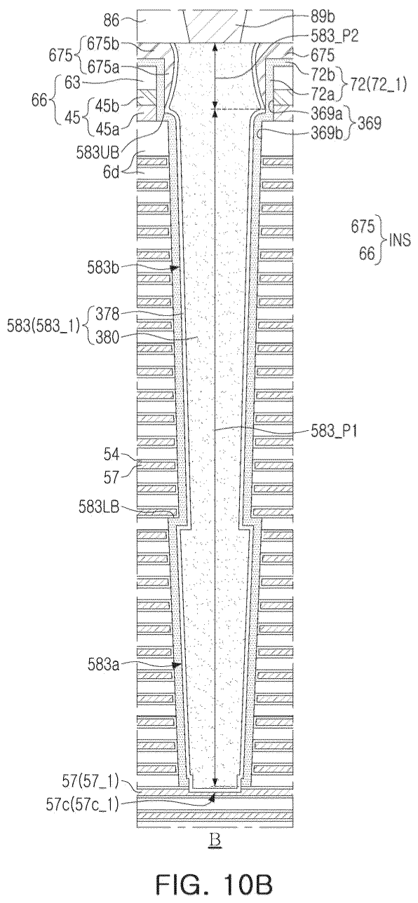

FIGS. 10A and 10B are partially enlarged cross-sectional views illustrating examples of the capping insulating layer 475 (see FIGS. 8A and 8B) and the gate contact plugs 383 (see FIGS. 8A and 8B) described above. FIG. 10A is a partially enlarged cross-sectional view corresponding to FIG. 8A, and FIG. 10B is a partially enlarged cross-sectional view corresponding to FIG. 8B.

In one or more example embodiments, referring to FIGS. 10A and 10B, the gate contact plugs 383 (see FIGS. 8A and 8B) including the first and second gate contact plugs 383_1 and 383_2 described above may be replaced with gate contact plugs 583 including first and second gate contact plugs 583_1 and 583_2 as in FIGS. 10A and 10B.

The capping insulating layer 475 (see FIGS. 8A and 8B) described above may be replaced with a capping insulating layer 675 including extension portions 675a extending from a portion covering an upper surface of the at least one intermediate insulating layer 66 to between side surfaces of the gate contact plugs 583 and the at least one intermediate insulating layer 66.

The capping insulating layer 675 may include a capping portion 675b disposed on the second spacer portion 72b on the upper surface of the at least one intermediate insulating layer 66 and the extension portions 675a extending from the capping portion 675b. The extension portions 675a may extend from the capping portion 675b between the first spacer portions 72a and the gate contact plugs 583.

The first gate contact plug 583_1 may include a first plug portion 583_P1 in contact with the first insulating spacer 72_1 and a second plug portion 583_P2 in contact with the capping insulating layer 675.

Lower ends of the extension portions 675a of the capping insulating layer 675 may be disposed at a lower level than the upper surface of the at least one intermediate insulating layer 66.

The extension portion 675a of the capping insulating layer 675 in contact with the first gate contact plug 583_1 may be disposed at a higher level than the uppermost gate electrode 57_2 among the gate electrodes 57.

In the first gate contact plug 583_1, an upper end of the first plug portion 583_P1 in contact with the first insulating spacer 72_1 and a lower end of the second plug portion 583_P2 in contact with the capping insulating layer 675 may be disposed at a higher level than the uppermost gate electrode 57_2 among the gate electrodes 57.

A side surface of the first gate contact plug 583_1 may include a first bent portion 583LB and a second bent portion 583UB corresponding to the first bent portion 383LB and the second bent portion 383UBa described above, respectively.

The first gate contact plug 583_1 may include a lower region 583a and an upper region 583b, which is disposed on the lower region 583a and at least a portion of which is disposed at a higher level than the uppermost gate electrode 57_2 among the gate electrodes 57.

The first gate contact plug 583_1 may have a concave side surface in a direction observed from a vertical center axis of the first gate contact plug 583_1 at the same level as the capping insulating layer 675.

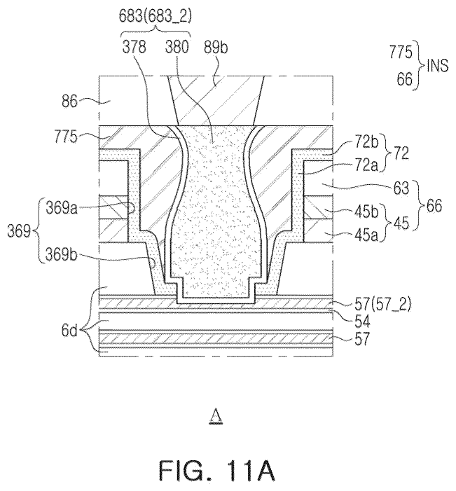

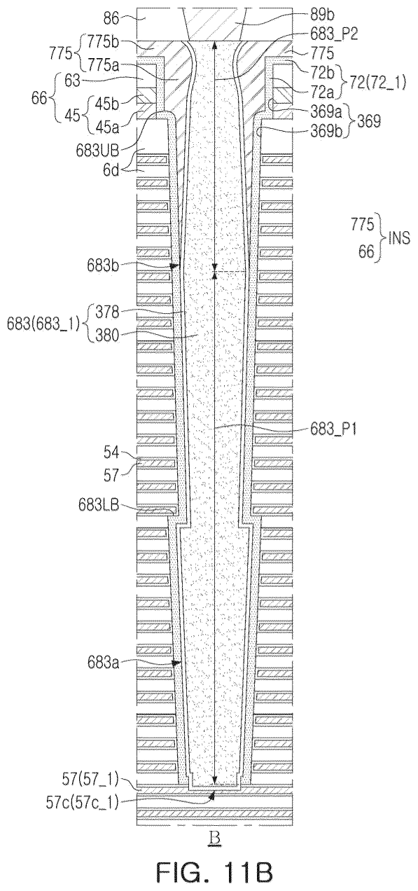

FIGS. 11A and 11B are partially enlarged cross-sectional views illustrating examples of the capping insulating layer 675 (see FIGS. 10A and 10B) and the gate contact plugs 583 (see FIGS. 10A and 10B) described above. FIG. 11A is a partially enlarged cross-sectional view corresponding to FIG. 10A, and FIG. 11B is a partially enlarged cross-sectional view corresponding to FIG. 10B.

In one or more example embodiments, referring to FIGS. 11A and 11B, the gate contact plugs 583 (see FIGS. 10A and 10B) including the first and second gate contact plugs 583_1 and 583_2 described above may be replaced with gate contact plugs 683 including the first and second gate contact plugs 683_1 and 683_2 as in FIGS. 11A and 11B.

The capping insulating layer 675 (see FIGS. 10A and 10B) described above may be replaced with a capping insulating layer 775 including extension portions 775a extending from a portion covering an upper surface of the at least one intermediate insulating layer 66 to between the side surfaces of the gate contact plugs 583 and the at least one intermediate insulating layer 66.

The capping insulating layer 775 may include a capping portion 775b disposed on the second spacer portion 72b on the upper surface of the at least one intermediate insulating layer 66 and the extension portions 775a extending from the capping portion 775b. The extension portions 775a may extend from the capping portion 775b to between the first spacer portions 72a and the gate contact plugs 683.

The first gate contact plug 683_1 may include a first plug portion 683_P1 in contact with the first insulating spacer 72_1 and a second plug portion 683_P2 in contact with the capping insulating layer 775.

A lower end of the extension portion 775a of the capping insulating layer 775 in contact with the first gate contact plug 683_1 may be disposed at a lower level than the uppermost gate electrode 57_2 among the gate electrodes 57.

In the first gate contact plug 683_1, an upper end of the first plug portion 683_P1 in contact with the first insulating spacer 72_1 and a lower end of the second plug portion 683_P2 in contact with the capping insulating layer 775 may be disposed at a lower level than the uppermost gate electrode 57_2 among the gate electrodes 57.

A side surface of the first gate contact plug 683_1 may include a first bent portion 683LB and a second bent portion 683UB at a higher level than the uppermost gate electrode 57_2.

The first gate contact plug 683_1 may include a lower region 683a and an upper region 683b, which is disposed on the lower region 683a and at least a portion of which is disposed at a higher level than the uppermost gate electrode 57_2 among the gate electrodes 57.

The first gate contact plug 683_1 may have a concave side surface in a direction observed from a vertical central axis of the first gate contact plug 683_1 at the same level as the capping insulating layer 775.

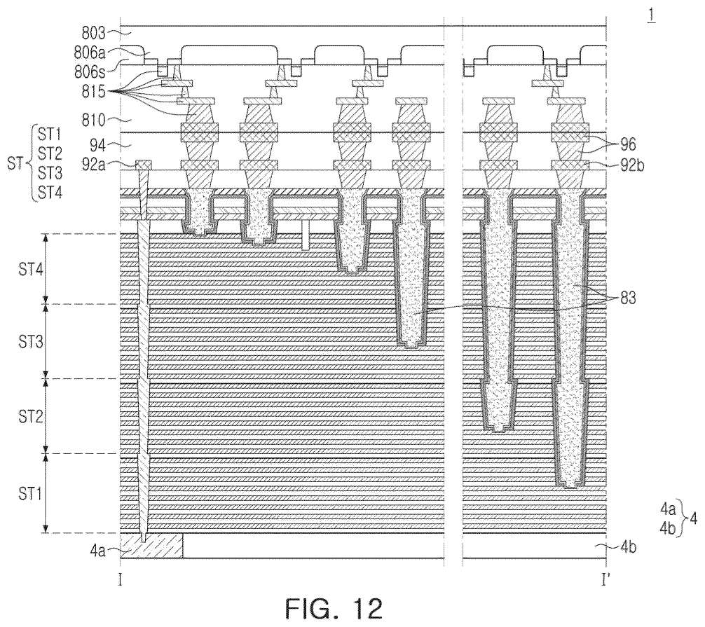

Next, referring to FIG. 12, an example of a semiconductor device including the example embodiments described above will be described. FIG. 12 is a cross-sectional view illustrating a region taken along line I-I′ of FIG. 1.

Referring to FIG. 1 and FIG. 12, the semiconductor device 1 may further include a first connection routing structure 96 embedded in the upper insulating structure 94 and electrically connected to the bit line 92a and the gate interconnection lines 92b.

The semiconductor device 1 may further include a peripheral structure PS disposed on the upper insulating structure 94.

The peripheral structure PS may include a substrate 803, a peripheral active region 806a below the substrate 803, and a peripheral element isolation region 806s defining the peripheral active region 806a below the substrate 803. The substrate 803 may be a semiconductor substrate.

The peripheral structure PS may further include a peripheral circuit PTR below the substrate 803, a second connection routing structure 815, and a peripheral insulating structure 810.

The peripheral circuit PTR may include a peripheral transistor. The peripheral transistor of the peripheral circuit PTR may include peripheral source/drain regions pSD spaced apart from each other within the peripheral active region 806a, a peripheral channel region pCH between the peripheral source/drain regions pSD, and peripheral gates pGO and pGE below the peripheral active region 806a.

The peripheral gates pGO and pGE may include a peripheral gate dielectric layer pGO and a peripheral gate electrode pGE below the peripheral gate dielectric layer (pGO). The second connection routing structure 815 may be embedded within the peripheral insulating structure 810 and may be electrically connected to the peripheral circuit PTR. The first connection routing structure 96 and the second connection routing structure 815 may be connected to each other.

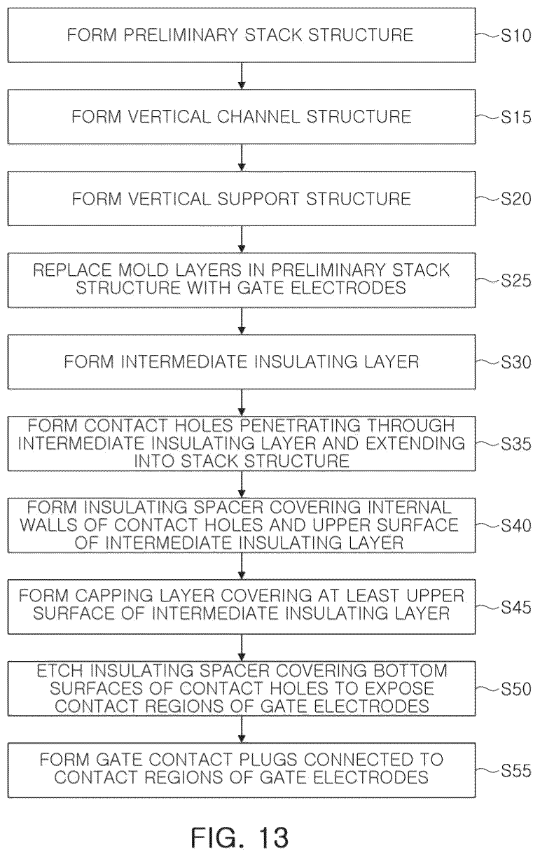

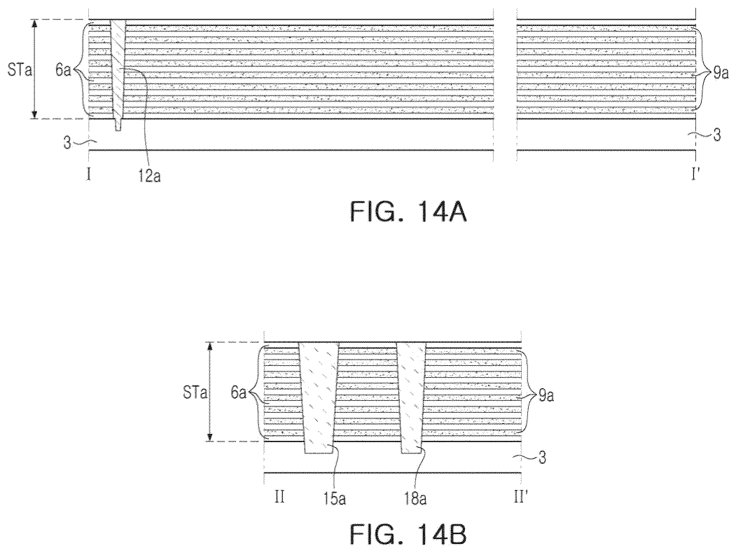

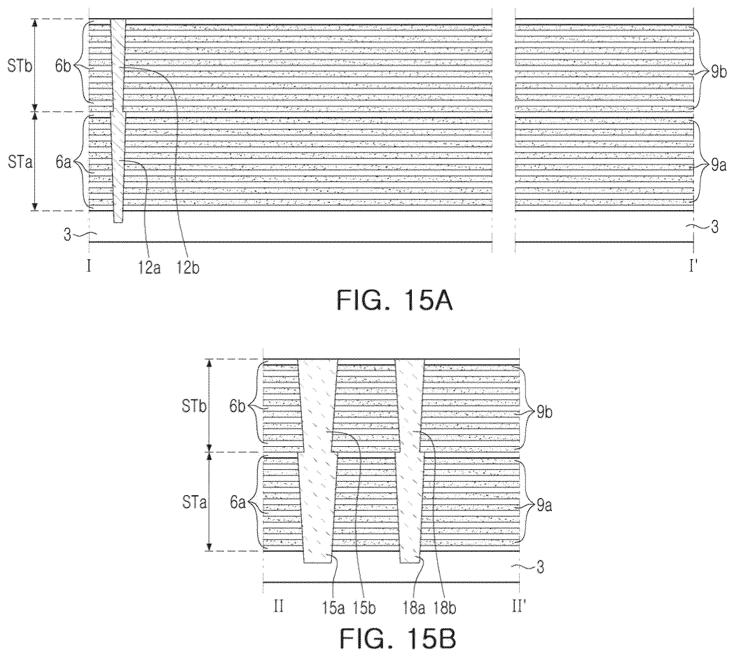

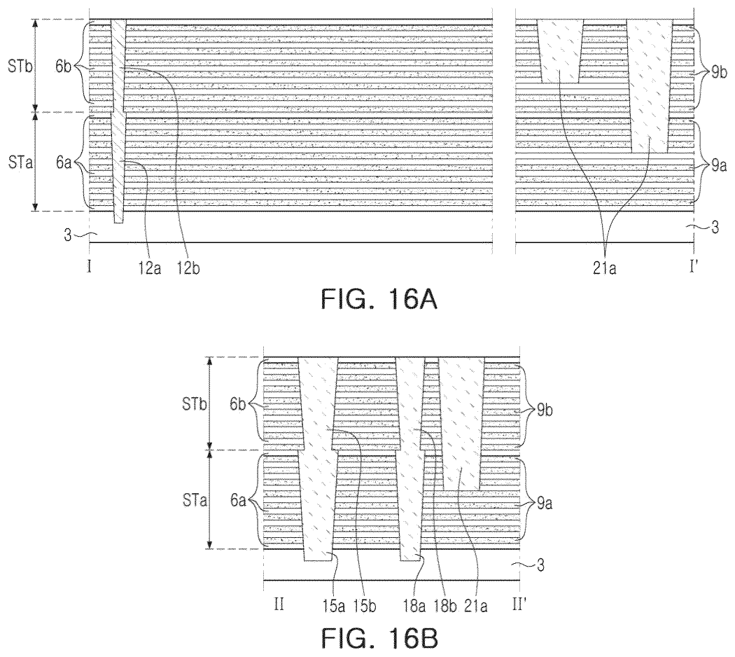

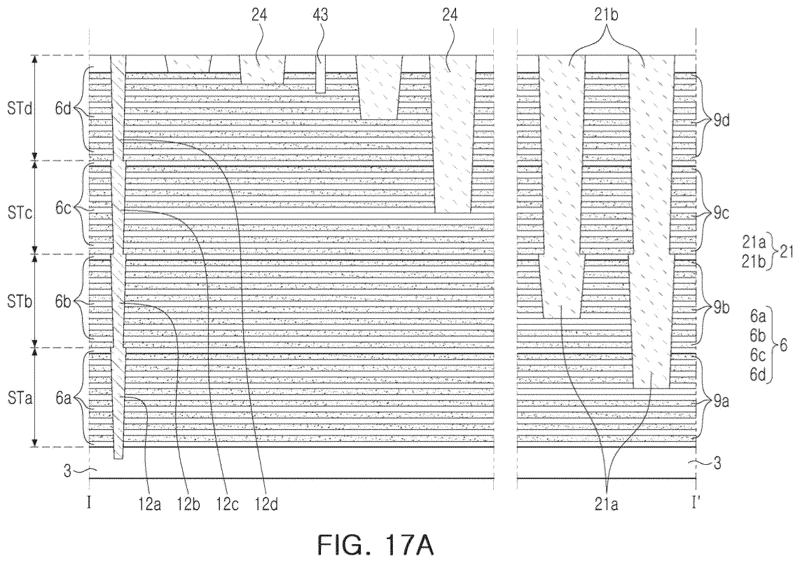

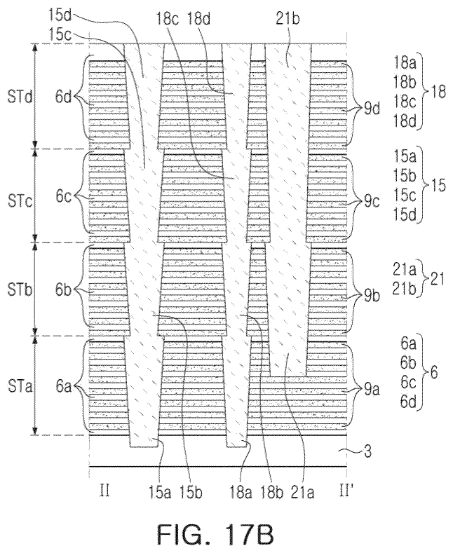

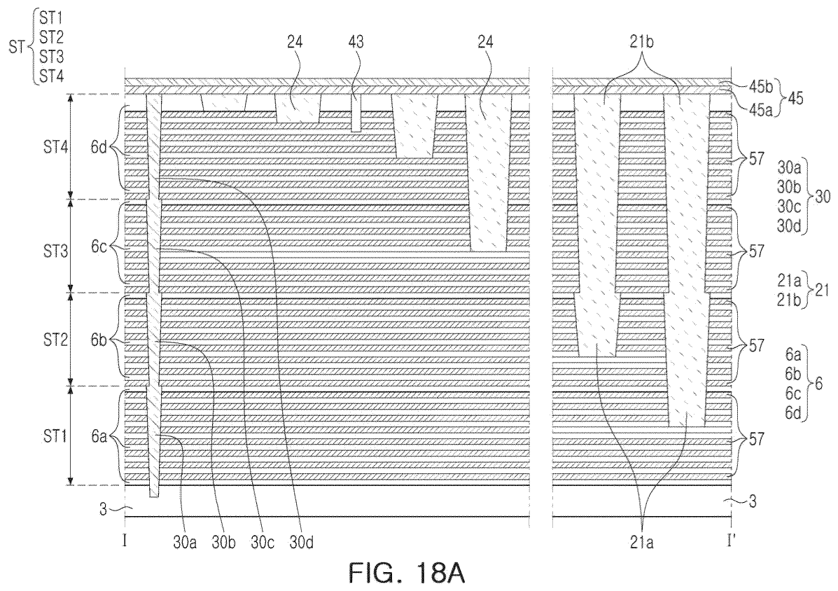

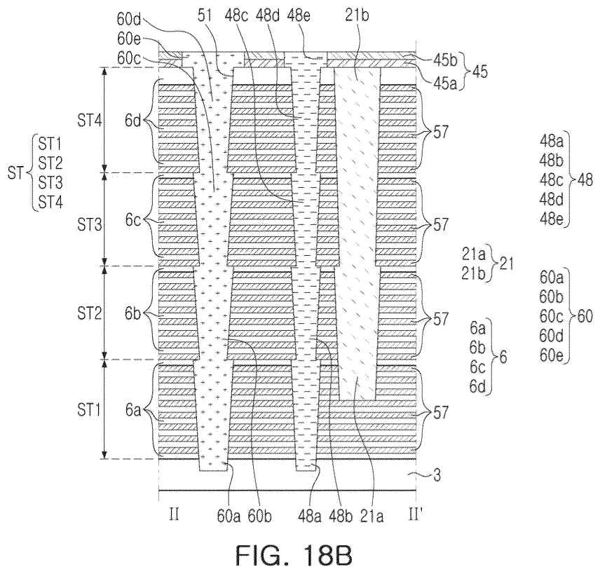

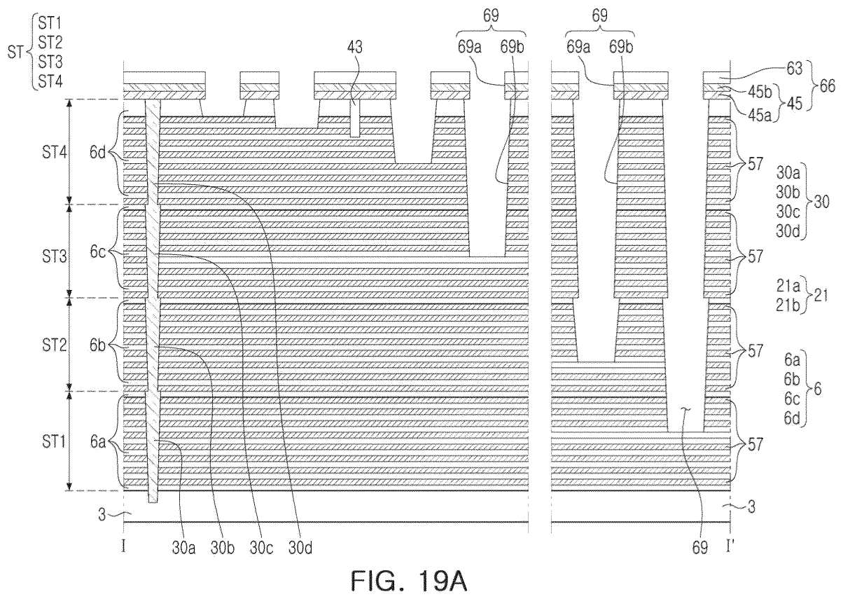

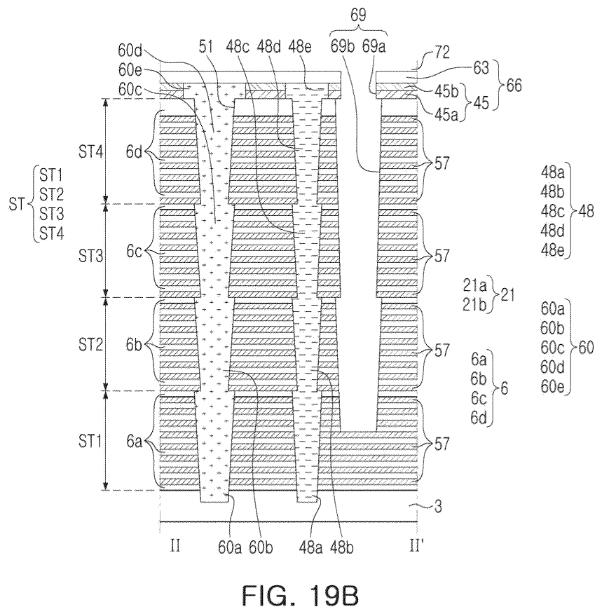

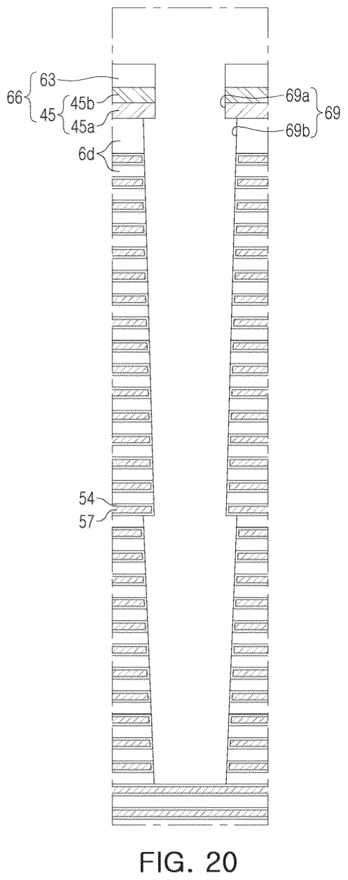

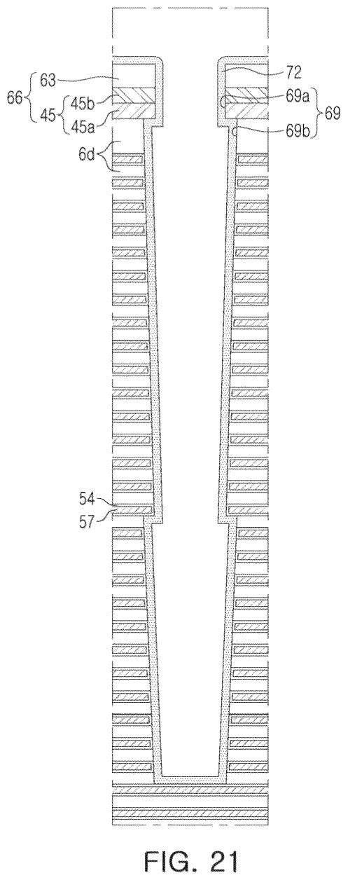

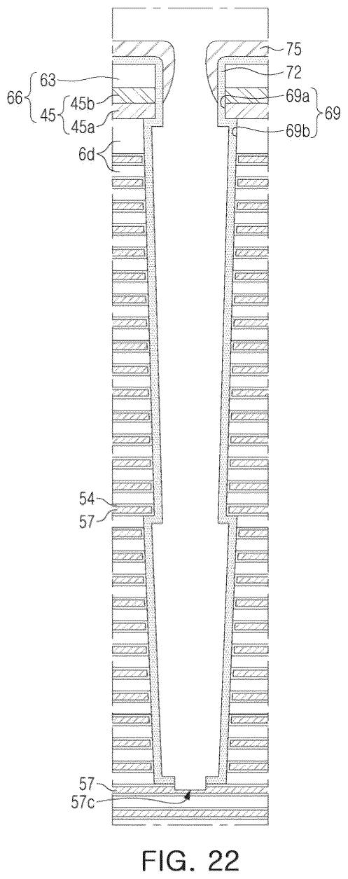

Next, an example of a semiconductor device manufacturing method according to an example embodiment of the present disclosure will be described. FIG. 13 is a process flow diagram illustrating a semiconductor device manufacturing method according to an example embodiment of the present disclosure, and FIGS. 14A, 14B, 15A, 15B, 16A, 16B, 17A, 17B, 18A, 18B, 19A, 19B, 20, 21, 22, 23 and 24 are views illustrating an example of a method of manufacturing a semiconductor device according to an example embodiment of the present disclosure. FIGS. 14A, 15A, 16A, 17A, 18A and 19A are cross-sectional views illustrating an area taken along line I-I′ of FIG. 1, FIGS. 14B, 15B, 16B, 17B, 18B and 19B are cross-sectional views illustrating an area taken along line II-II′ of FIG. 1, and FIGS. 20, 21, 22, 23 and 24 are enlarged views of a portion marked with ‘B’ of FIG. 2A.

Referring to FIGS. 14A and 14B, a first preliminary stacked portion STa may be formed on a base 3. The first preliminary stacked portion STa may include first interlayer insulating layers 6a and first mold layers 9a which are alternately stacked. The base 3 may be a semiconductor substrate. A first preliminary vertical channel portion 12a, a first preliminary vertical separation portion 15a and a first preliminary vertical support portion 18a, which penetrate through the first preliminary stacked portion Sta, may be formed.

Referring to FIGS. 15A and 15B, a second preliminary stacked portion STb may be formed on the first preliminary stacked portion STa. The second preliminary stacked portion STb may include second interlayer insulating layers 6b and second mold layers 9b which are alternately stacked. A second preliminary vertical channel portion 12b, a second preliminary vertical separation portion 15b and a second preliminary vertical support portion 18b, which penetrate through the second preliminary stacked portion STb, may be formed.

Referring to FIGS. 16A and 16B, photo and etching processes may be repeatedly performed on the first preliminary stacked portion STa and the second preliminary stacked portion STb to form plug lower regions 21a.

Referring to FIGS. 13, 17A and 17B, a third preliminary stacked portion STc may be formed on the second preliminary stacked portion STb. The third preliminary stacked portion STc may include third interlayer insulating layers 6c and third mold layers 9c which are alternately stacked. A third preliminary vertical channel portion 12c, a third preliminary vertical separation portion 15c, and a third preliminary vertical support portion 18c, which penetrate through the third preliminary stacked portion STc, may be formed.

A fourth preliminary stacked portion STd may be formed on the third preliminary stacked portion STc. The fourth preliminary stacked portion STd may include fourth interlayer insulating layers 6d and fourth mold layers 9d which are alternately stacked. A fourth preliminary vertical channel portion 12d, a fourth preliminary vertical separation portion 15d and a fourth preliminary vertical support portion 18d which penetrate through the fourth preliminary stacked portion STd may be formed.

The first to fourth interlayer insulating layers 6a, 6b, 6c and 6d may form interlayer insulating layers 6, and the first to fourth mold layers 9a, 9b, 9c and 9d may form mold layers 9a, 9b, 9c and 9d. The interlayer insulating layers 6 may be formed of silicon oxide, and the mold layers 9a, 9b, 9c and 9d may be formed of a silicon nitride.

Preliminary stack structures STa, STb, STc and STd may be formed (S10). The preliminary stack structure STa, STb, STc and STd may include the first to fourth preliminary stacked portions STa, STb, STc and STd. The preliminary stack structure STa, STb, STc and STd may include the interlayer insulating layers 6 and the mold layers 9a, 9b, 9c and 9d, which are alternately stacked.

The first to fourth preliminary vertical channel portions 12a, 12b, 12c and 12d may be connected to each other. The first to fourth preliminary vertical separation portions 15a, 15b, 15c and 15d may be connected to each other. The first to fourth preliminary vertical support portions 18a, 18b, 18c and 18d may be connected to each other.

For the third preliminary stacked portion STc and the fourth preliminary stacked portion STd, photo and etching processes may be repeatedly performed to form first plug upper regions 21b connected to the plug lower regions 21a and second plug upper regions 24. The plug lower regions 21a and the first plug upper regions 21b may form plug regions 21.

Referring to FIG. 13, FIG. 18A and FIG. 18B, a vertical channel structure 30 may be formed (S15). Forming the vertical channel structure 30 may include removing the first to fourth preliminary vertical channel portions 12a, 12b, 12c and 12d to form a channel hole, sequentially forming the data storage structure 33 (see FIG. 4) and the channel layer 36 (see FIG. 4) conformally covering an inner wall of the channel hole, forming an insulating core pattern 39 (see FIG. 4) partially filling the channel hole on the channel layer 36 (see FIG. 4), and forming the pad pattern 42 (see FIG. 4) filling the remaining portion of the channel hole on the insulating core pattern 39 (see FIG. 4). The vertical channel structure 30 including the first to fifth vertical channel portions 30a, 30b, 30c and 30d as in FIG. 4 may be formed.

The first intermediate insulating layer 45 (see FIG. 4) may be formed on the fourth preliminary stacked portion STd. The first intermediate insulating layer 45 may include the first-first intermediate insulating layer 45a and the first-second intermediate insulating layer 45b on the first-first intermediate insulating layer 45a.

The vertical support structure 48 (see FIG. 4) may be formed (S20). Forming the vertical support structure 48 may include forming an upper supporter hole penetrating through the first intermediate insulating layer 45 and exposing the fourth preliminary vertical supporter portion 18d, removing the first to fourth preliminary vertical supporter portions 18a, 18b, 18c and 18d exposed by the upper supporter hole to form a lower supporter hole, and filling the lower and upper supporter holes with an insulating material. Accordingly, the vertical support structure 48 including the first to fifth vertical supporter portions 48a, 48b, 48c, 48d and 48e as in FIG. 2B may be formed.

The mold layers 9a, 9b, 9c and 9d in the preliminary stack structures STa, STb, STc and STd may be replaced with gate electrodes 57 (S25). The preliminary stack structures STa, STb, STc and STd may be formed as a stack structure ST including first to fourth stacked portions ST1, ST2, ST3 and ST4.

Replacing the mold layers 9a, 9b, 9c and 9d within the above-described preliminary stack structures STa, STb, STc and STd with the gate electrodes 57 may include forming a separation trench 51 penetrating through the preliminary stack structures STa, STb, STc and STd and the first intermediate insulating layer 45, removing the mold layers 9a, 9b, 9c and 9d exposed by the separation trench 51 to form empty spaces, and forming the gate electrodes 57 within the empty spaces. Forming the separation trench 51 may include forming an upper separation trench penetrating through the first intermediate insulating layer 45 and exposing the fourth preliminary vertical separation portion 15d, and removing the first to fourth preliminary vertical separation portions 15a, 15b, 15c and 15d to form a lower separation trench.

Before forming the gate electrodes 57 in the empty spaces, forming gate dielectric layers 54 (see FIGS. 3A and 3B) conformally covering the empty spaces may be further included.

A separation structure 60 may be formed in the separation trench 51. Accordingly, the separation structure 60 including the first to fifth vertical separation portions 60a, 60b, 60c, 60d and 60e as in FIG. 2B may be formed.

Referring to FIG. 13, FIG. 19A, FIG. 19B and FIG. 20, an intermediate insulating layer 63 may be formed (S30). The intermediate insulating layer 63 may be a second intermediate insulating layer 63. The first and second intermediate insulating layers 45 and 63 may form at least one intermediate insulating layer 66.

Contact holes 69 penetrating through the intermediate insulating layer 63 and extending into the stack structure ST may be formed (S35).

Forming the contact holes 69 may include forming upper contact holes 69a penetrating through the at least one intermediate insulating layer 66 and exposing the plug regions 21 and the second plug upper regions 24, and removing the plug regions 21 and the second plug upper regions 24 exposed by the upper contact holes 69a to form lower contact holes 69b.

In one example, a width of each of the upper contact holes 69a may be less than width of each of the lower contact holes 69b adjacent to the upper contact holes 69a.

In another example, the upper contact holes 69a may be formed as upper contact holes 369, having a width greater than the width of each of the lower contact holes 69b, as in FIGS. 8A and 8B.

Referring to FIGS. 13 and 21, an insulating spacer 72 covering internal walls of the contact holes 69 and an upper surface of the intermediate insulating layer 63 may be formed (S40). The insulating spacer 72 may be formed of an oxide-based insulating material (e.g., a silicon oxide, or the like). The insulating spacer 72 may be formed conformally.

Referring to FIG. 13 and FIG. 22, a capping insulating layer 75 covering at least the upper surface of the intermediate insulating layer 63 may be formed (S45). For example, forming the capping insulating layer 75 may include forming a material layer having poor step coverage as compared to the insulating spacer 72, and isotropically etching the material layer such that the material layer on bottom surfaces of the contact holes 69 is completely removed, while the material layer remains on an upper surface of the intermediate insulating layer 63 and may also remain on sidewalls of the upper contact holes 69a. A material of the capping insulating layer 75 may be a different material from the materials of the interlayer insulating layers 6 and the insulating spacer 72.

The insulating spacer 72 covering the bottom surfaces of the contact holes 69 may be etched to expose the contact regions 57c of the gate electrodes 57 (S50). For example, exposing the contact regions 57c of the gate electrodes 57 may include anisotropically etching the insulating spacer 72 by performing an anisotropic etching process using the capping insulating layer 75 as an etching mask.

Referring to FIGS. 13 and 23, a capping insulating layer 175 having a reduced size may be formed by isotropically etching the capping insulating layer 75 such that a capping insulating layer formed on side surfaces of the upper contact holes 69a is removed. According to an example embodiment, a size of the capping insulating layer may be controlled by controlling an isotropic etching process of isotropically etching the capping insulating layer 75 such that the capping insulating layer formed on the side surfaces of the upper contact holes 69a is removed. Accordingly, the capping insulating layer 275 as in FIGS. 5A and 5B may be formed, or the capping insulating layer 75 as in FIGS. 6A and 6B in which the capping insulating layer formed on the side surfaces of the upper contact holes 69a remains may be formed.

The capping insulating layer 175 and the at least one intermediate insulating layer 66 may form an insulating structure INS.

Referring to FIGS. 13 and 24, gate contact plugs 83 connected to the contact regions 57c of the gate electrodes 57 may be formed (S55).

Forming the gate contact plugs 83 may include forming a conductive material layer filling the contact holes 69 on a structure formed up to the capping insulating layer 175 and covering an upper surface of the capping insulating layer 75, and planarizing the conductive material layer until the upper surface of the capping insulating layer 75 is exposed. Each of the gate contact plugs 83 may include a plug material pattern 80 and a conductive liner 78 covering a side surface and lower surfaces of the plug pattern 80.

Referring again to FIGS. 1, 2A, 2B, 3A, 3B and 4, the upper insulating layer 86 may be formed on the capping insulating layer 175. The upper insulating layer 86 may be formed of an oxide-based insulating material (e.g., silicon oxide, or the like).

The bit line stud 89a penetrating through the upper insulating layer 86 and the insulating structure INS and connected to the vertical channel structure 30, and the gate studs 89b penetrating through the upper insulating layer 86 and connected to the gate contact plugs 83 may be formed.

The bit line 92a connected to the bit line stud 89a and the gate interconnection lines 92b connected to the gate studs 89b may be formed on the upper insulating layer 86. The bit line 92a may be disposed at the same level as the gate interconnection lines 92b.

The upper insulating structure 94 covering the bit line 92a and the gate interconnection lines 92b may be formed on the upper insulating layer 86.

The base 3 may be removed to expose the vertical channel structure 30, the data storage structure 33 of the exposed vertical channel structure 30 may be etched to expose the channel layer 36, and the pattern structure 4 may be formed. The pattern structure 4 may include the first pattern structure 4a connected to the channel layer 36 and the second pattern structure 4b on a side surface of the first pattern structure 4a. The first pattern structure 4a may be a common source, and the second pattern structure 4b may include an insulating material.

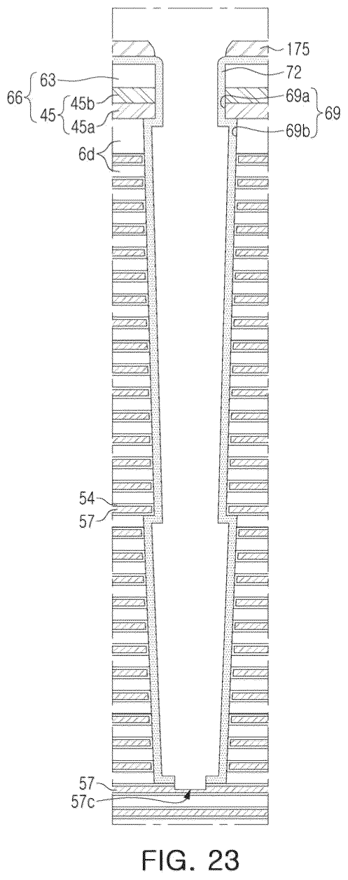

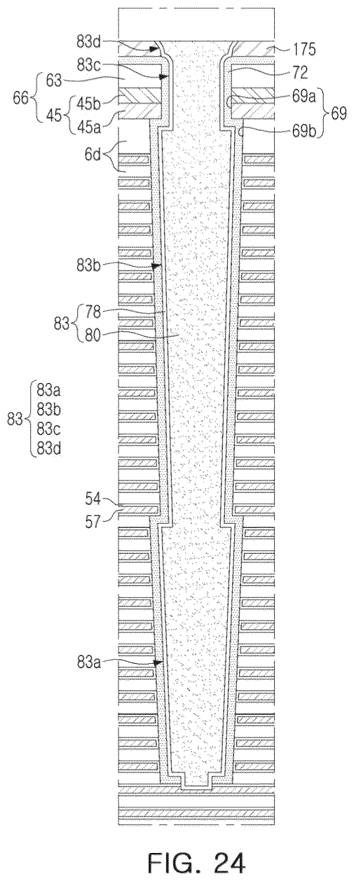

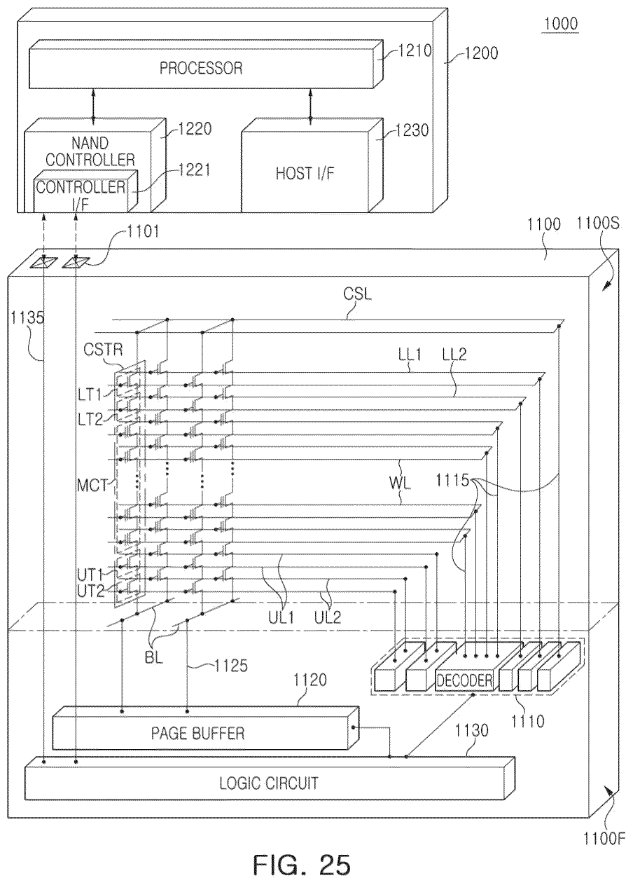

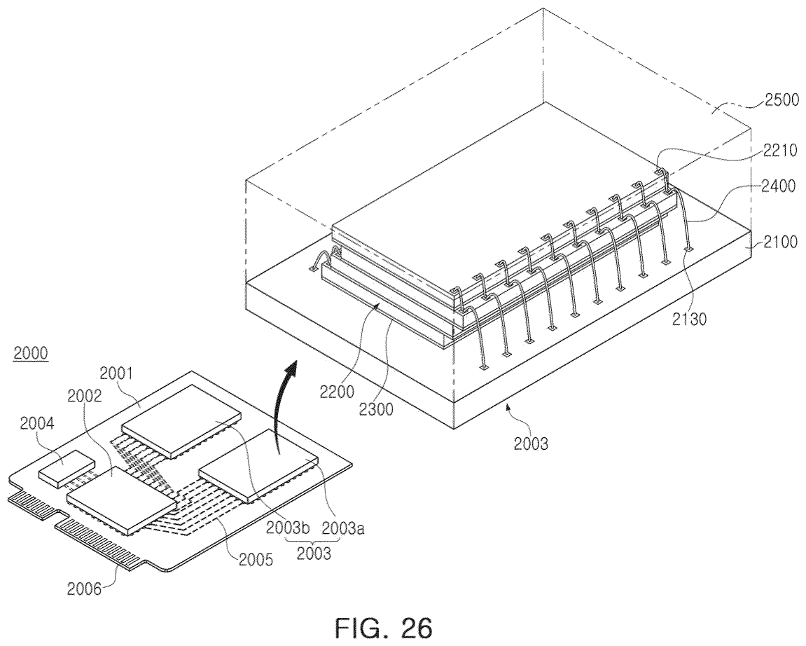

Next, a data storage system including a semiconductor device according to an example embodiment of the present disclosure will be described with reference to FIGS. 25 and 26, respectively.

FIG. 25 is a schematic diagram illustrating a data storage system including a semiconductor device according to an example embodiment of the present disclosure.

Referring to FIG. 25, a data storage system 1000 according to an example embodiment of the present disclosure may include a semiconductor device 1100 and a controller 1200 electrically connected to the semiconductor device 1100 to control the semiconductor device 1100. The data storage system 1000 may be a storage device including the semiconductor device 1100 or an electronic device including the storage device. For example, the data storage system 1000 may be a solid state drive device (SSD), a Universal Serial Bus (USB), a computing system, a medical device, or a communication device, including the semiconductor device 1100.

In an example embodiment, the data storage system 1000 may be an electronic system that stores data.

The semiconductor device 1100 may be a nonvolatile memory device. For example, the semiconductor device 1110 may be a semiconductor device according to one of the example embodiments described above with reference to FIGS. 1 to 12. The semiconductor device 1100 may include a first structure 1100F and a second structure 1100S on the first structure 1100F.

The first structure 1100F may be a peripheral circuit structure including a decoder circuit 1110, a page buffer 1120 and a logic circuit 1130.

The second structure 1100S may be a memory structure including bit lines BL, common sources CSL, word lines WL, first and second gate upper lines UL1 and UL2, first and second gate lower lines LL1 and LL2, and memory cell strings CSTR between the bit line BL and the common source CSL.

In the second structure 1100S, each memory cell string CSTR may include lower transistors LT1 and LT2 adjacent to the common source CSL, upper transistors UT1 and UT2 adjacent to the bit line BL, and a plurality of memory cell transistors MCT disposed between the lower transistors LT1 and LT2 and the upper transistors UT1 and UT2. A number of the lower transistors LT1 and LT2 and a number of the upper transistors UT1 and UT2 may be variously changed depending on the example embodiments.

The plurality of memory cell transistors MCT may include gate layers GL_L and GL_U that may be word lines, among the gate layers GL_L and GL_U, the channel layer 63, and the data storage structure 60.

In example embodiments, the upper transistors UT1 and UT2 may include string select transistors, and the lower transistors LT1 and LT2 may include ground select transistors. The gate lower lines LL1 and LL2 may be gate electrodes of the lower transistors LT1 and LT2, respectively. The word lines WL may be gate electrodes of memory cell transistors MCT, and the gate upper lines UL1 and UL2 may be gate electrodes of the upper transistors UT1 and UT2, respectively.

The gate layers GL_L and GL_U may include the gate lower lines LL1 and LL2, the word lines WL, and the gate upper lines UL1 and UL2. The gate layers GL_L and GL_U may be the gate electrodes 57 (see FIGS. 1 to 12) described above.

The common source CSL, the first and second gate lower lines LL1 and LL2, the word lines WL, and the first and second gate upper lines UL1 and UL2 may be electrically connected to the decoder circuit 1110 through first interconnection lines 1115 extending from the first structure 1100F to the second structure 1100S.

The bit lines BL may be electrically connected to the page buffer 1120 through second interconnection lines 1125 extending from the first structure 1100F to the second structure 1100S.

In the first structure 1100F, the decoder circuit 1110 and the page buffer 1120 may execute a control operation for at least one selected memory cell transistor MCT among the plurality of memory cell transistors MCT. The decoder circuit 1110 and the page buffer 1120 may be controlled by a logic circuit 1130.

The semiconductor device 1000 may further include an input/output pad 1101. The semiconductor device 1000 may communicate with the controller 1200 through the input/output pad 1101 electrically connected to the logic circuit 1130. The input/output pad 1101 may be electrically connected to the logic circuit 1130 through an input/output interconnection line 1135 extending from the first structure 1100F to the second structure 1100S. Accordingly, the controller 1200 may be electrically connected to the semiconductor device 1000 through the input/output pad 1101 and may control the semiconductor device 1000.

The controller 1200 may include a processor 1210, a NAND controller 1220, and a host interface 1230. According to example embodiments, the data storage system 1000 may include a plurality of semiconductor devices 1100, and in this case, the controller 1200 may control the plurality of semiconductor devices 1000.

The processor 1210 may control an overall operation of the data storage system 1000 including the controller 1200. The processor 1210 may operate according to a predetermined firmware, and may control the NAND controller 1220 to access the semiconductor device 1100. The NAND controller 1220 may include a NAND interface 1221 processing communication with the semiconductor device 1100. Through the NAND interface 1221, a control command for controlling the semiconductor device 1100, data to be written to the memory cell transistors MCT of the semiconductor device 1100, data to be read from the memory cell transistors MCT of the semiconductor device 1100, or the like, may be transmitted. The host interface 1230 may provide a communication function between the data storage system 1000 and an external host. When receiving a control command from the external host through the host interface 1230, the processor 1210 may control the semiconductor device 1100 based on the control command.

FIG. 26 is a perspective view schematically illustrating a data storage system including a semiconductor device according to an example embodiment of the present disclosure.

Referring to FIG. 26, a data storage system 2000 according to an example embodiment of the present disclosure may include a main board 2001, a controller 2002 mounted on the main board 2001, one or more semiconductor packages 2003, and a DRAM 2004. The semiconductor package 2003 and the DRAM 2004 may be connected to the controller 2002 by interconnection patterns 2005 formed on the main board 2001. The main board 2001 may include a connector 2006 including a plurality of pins coupled to the external host. A number and an arrangement of the plurality of pins in the connector 2006 may vary depending on a communication interface between the data storage system 2000 and the external host. In example embodiments, the data storage system 2000 may communicate with the external host according to any one of interfaces including, for example but not limited to, Universal Serial Bus (USB), Peripheral Component Interconnect Express (PCI-Express), Serial Advanced Technology Attachment (SATA), and M-Phy for Universal Flash Storage (UFS). In example embodiments, the data storage system 2000 may operate by power supplied from the external host through the connector 2006. The data storage system 2000 may further include a Power Management Integrated Circuit (PMIC) distributing power supplied from the external host to the controller 2002 and the semiconductor package 2003.

The controller 2002 may write data to the semiconductor package 2003, or may read data from the semiconductor package 2003, and may improve an operating speed of the data storage system 2000.

The DRAM 2004 may be a buffer memory for alleviating a speed difference between the semiconductor package 2003, which is a data storage space, and the external host. The DRAM 2004 included in the data storage system 2000 may also operate as a kind of cache memory, and may provide a space for temporarily storing data in a control operation for the semiconductor package 2003. In the case in which the data storage system 2000 includes the DRAM 2004, the controller 2002 may further include a DRAM controller for controlling the DRAM 2004 in addition to a NAND controller for controlling the semiconductor package 2003.

The semiconductor package 2003 may include first and second semiconductor packages 2003a and 2003b spaced apart from each other. Each of the first and second semiconductor packages 2003a and 2003b may be a semiconductor package including a plurality of semiconductor chips 2200. Each of the semiconductor chips 2200 may include a semiconductor device according to any one of the example embodiments described above with reference to FIGS. 1 to 12.

Each of the first and second semiconductor packages 2003a and 2003b may include a package substrate 2100, semiconductor chips 2200 on the package substrate 2100, adhesive layers 2300 disposed on lower surfaces of each of the semiconductor chips 2200, a connection structure 2400 electrically connecting the semiconductor chips 2200 and the package substrate 2100, and a molding layer 2500 covering the semiconductor chips 2200 and the connection structure 2400 on the package substrate 2100.

The package substrate 2100 may be a printed circuit board including package upper pads 2130. Each of the semiconductor chips 2200 may include an input/output pad 2210.

In example embodiments, the connection structure 2400 may be a bonding wire electrically connecting the input/output pad 2210 and the package upper pads 2130. Accordingly, in each of the first and second semiconductor packages 2003a and 2003b, the semiconductor chips 2200 may be electrically connected to each other in a bonding wire manner, and may be electrically connected to the package upper pads 2130 of the package substrate 2100. According to example embodiments, in each of the first and second semiconductor packages 2003a and 2003b, the semiconductor chips 2200 may be electrically connected to each other by a connection structure including a through-silicon via (TSV), instead of the connection structure 2400 in a bonding wire manner.

In example embodiments, the controller 2002 and the semiconductor chips 2200 may be included in a single package. For example, the controller 2002 and the semiconductor chips 2200 may be mounted on a separate interposer substrate different from the main substrate 2001, and the controller 2002 and the semiconductor chips 2200 may be connected to each other by interconnection lines formed on the interposer substrate. In the semiconductor package 2003, the package substrate 2100 may be a printed circuit board. Each of the semiconductor chips 2200 may include a semiconductor device according to any one of the example embodiments described above with reference to FIGS. 1 to 12.

According to an aspect of one or more example embodiments, a semiconductor device manufacturing method includes: forming a stack structure including stacked portions, each stacked portion including gate electrodes and interlayer insulating layers alternately stacked in a vertical direction; forming at least one intermediate insulating layer on the stack structure; forming contact holes penetrating through the at least one intermediate insulating layer and extending into the stack structure; forming an insulating spacer covering internal walls of the contact holes and an upper surface of the at least one intermediate insulating layer; forming a capping insulating layer covering at least the upper surface of the at least one intermediate insulating layer; etching the insulating spacer covering bottom surfaces of the contact holes to expose contact regions of the gate electrodes; and filling the contact holes with a conductive material layer, to form gate contact plugs connected to the contact regions of the gate electrodes.

According to some embodiments, the forming the stack structure nay include forming preliminary stack structures each including the interlayer insulating layers and mold layers which are alternately stacked; forming a vertical channel structure penetrating through the stack structure; and replacing the mold layers in the preliminary stack structures with the gate electrodes.

According to some embodiments, the replacing the mold layers with the gate electrodes may include forming a separation trench penetrating through the preliminary stack structures and a first intermediate insulating layer of the at least one intermediate insulating layer, removing the mold layers exposed by the separation trench to form empty spaces; and forming the gate electrodes within the empty spaces.

According to some embodiments, the exposing the contact regions of the gate electrodes may include anisotropically etching the insulating spacer by performing an anisotropic etching process using the capping insulating layer as an etching mask.

According to some embodiments, the filling the contact holes may include filling the contact holes with the conductive material layer on a structure formed up to the capping insulating layer and covering an upper surface of the capping insulating layer, and planarizing the conductive material layer until the upper surface of the capping insulating layer is exposed.

According to example embodiments, a semiconductor device including gate electrodes stacked in a vertical direction and gate contact plugs connected to contact regions of these gate electrodes may be provided.

According to example embodiments, each of the gate contact plugs may include a first plug portion in contact with an insulating spacer formed of a first material and a second plug portion in contact with a capping insulating layer formed of a second material different from the first material. Since a structure including the gate contact plugs, the insulating spacer and the capping insulating layer may prevent electrical shorts between the gate contact plugs and the gate electrodes, performance of the semiconductor device may be improved.

Advantages and effects of the present application are not limited to the foregoing content and may be more easily understood in the process of describing a specific example embodiment of the present disclosure.

Although example embodiments of the present disclosure have been described with reference to the accompanying drawings, it will be understood by those skilled in the art that the present disclosure may be implemented in other specific forms without changing its technical concepts or essential features. Therefore, it should be understood that the example embodiments described above are merely examples only and not limited in all respects.

What is claimed is:

1. A semiconductor device, comprising:
a stack structure including gate electrodes and interlayer insulating layers alternately stacked in a vertical direction;
a vertical channel structure penetrating through the stack structure and including a data storage layer;
an insulating structure on the stack structure;
gate contact plugs penetrating through the insulating structure and extending downwardly and connected to contact regions of the gate electrodes; and
insulating spacers on side surfaces of the gate contact plugs,
wherein the insulating structure includes at least one intermediate insulating layer on the stack structure and a capping insulating layer on the at least one intermediate insulating layer,
wherein a material of the capping insulating layer is different from a material of the insulating spacers, and
wherein a first gate contact plug of the gate contact plugs includes a first plug portion in contact with a first insulating spacer of the insulating spacers and a second plug portion in contact with the capping insulating layer.

2. The semiconductor device of claim 1, wherein the first gate contact plug includes:
a first upper region, at least a portion of which is at a higher level than an uppermost gate electrode of the gate electrodes;
a second upper region on the first upper region and having a width different from a width of the first upper region; and
a third upper region on the second upper region and having a width different from a width of the second upper region.

3. The semiconductor device of claim 2, wherein a width of the first upper region adjacent to the second upper region is greater than a width of the second upper region adjacent to the first upper region.

4. The semiconductor device of claim 3, wherein a width of an upper surface of the third upper region is greater than a width of a middle portion of the second upper region between the first upper region and the third upper region.

5. The semiconductor device of claim 1, wherein the first gate contact plug includes:
a first upper region, at least a portion of which is at a higher level than an uppermost gate electrode of the gate electrodes;
a second upper region on the first upper region and having a width different from a width of the first upper region;
a third upper region, which is on the second upper region and is at a same level as the capping insulating layer, and
wherein a difference between a width of an upper surface of the third upper region and a width of the third upper region adjacent to the second upper region is greater than a difference between a width of the second upper region adjacent to the first upper region and a width of the second upper region adjacent to the third upper region.

6. The semiconductor device of claim 1, wherein the capping insulating layer includes an extension portion extending from a portion covering an upper surface of the at least one intermediate insulating layer to a portion between the side surfaces of the gate contact plugs and the at least one intermediate insulating layer.

7. The semiconductor device of claim 6, wherein the first gate contact plug has a concave side surface in a direction observed from a vertical center axis of the first gate contact plug, at a same level as the capping insulating layer.

8. The semiconductor device of claim 6, wherein the extension portion of the capping insulating layer is at a higher level than an uppermost gate electrode of the gate electrodes.

9. The semiconductor device of claim 6, wherein the first gate contact plug is connected to a first gate electrode at a lower level than an uppermost gate electrode of the gate electrodes, and
wherein a lower end of the extension portion of the capping insulating layer is at a lower level than the uppermost gate electrode.

10. The semiconductor device of claim 1, wherein the first gate contact plug includes:
a first upper region, at least a portion of which is at a higher level than an uppermost gate electrode of the gate electrodes;
a second upper region on the first upper region and having a width greater than a width of the first upper region; and
a third upper region on the second upper region and having a width greater than a width of the second upper region.

11. The semiconductor device of claim 1, wherein the first gate contact plug includes:
a first upper region, at least a portion of which is at a higher level than an uppermost gate electrode of the gate electrodes;
a second upper region on the first upper region and having a width greater than a width of the first upper region; and
a third upper region on the second upper region and at a same level as the capping insulating layer, and
wherein a difference between a width of an upper surface of the third upper region and a width of the third upper region adjacent to the second upper region is greater than a difference between a width of the second upper region adjacent to the first upper region and a width of the second upper region adjacent to the third upper region.

12. The semiconductor device of claim 1, wherein the capping insulating layer has an upper surface, coplanar with upper surfaces of the gate contact plugs.

13. The semiconductor device of claim 1, further comprising:
a bit line on the vertical channel structure; and
a bit line stud between the bit line and the vertical channel structure.

14. The semiconductor device of claim 13, further comprising:
a gate interconnection line on the first gate contact plug; and
a gate stud between the gate interconnection line and the first gate contact plug, wherein the bit line is at a same level as the gate interconnection line.

15. A semiconductor device, comprising:
a stack structure including gate electrodes and interlayer insulating layers alternately stacked in a vertical direction;
a vertical channel structure penetrating through the stack structure and including a data storage layer;
an insulating structure on the stack structure; and
gate contact plugs penetrating through the insulating structure and extending downwardly and connected to contact regions of the gate electrodes,
wherein the insulating structure includes at least one intermediate insulating layer on the stack structure and a capping insulating layer on the at least one intermediate insulating layer,
wherein the at least one intermediate insulating layer includes a material different from a material of the capping insulating layer,
wherein the capping insulating layer has an upper surface, coplanar with upper surfaces of the gate contact plugs, and
wherein a side surface of a first gate contact plug of the gate contact plugs includes at least one bent portion at a higher level than an upper surface of an uppermost gate electrode of the gate electrodes.

16. The semiconductor device of claim 15, further comprising:
insulating spacers on side surfaces of the gate contact plugs,
wherein the material of the capping insulating layer is different from a material of the insulating spacers.

17. The semiconductor device of claim 16, wherein the insulating spacers extend between the capping insulating layer and the at least one intermediate insulating layer.

18. The semiconductor device of claim 15, wherein the capping insulating layer includes an extension portion extending from a portion covering an upper surface of the at least one intermediate insulating layer to a portion between side surfaces of the gate contact plugs and the at least one intermediate insulating layer.

19. A data storage system, comprising:
a semiconductor device including an input/output pad; and
a controller electrically connected to the semiconductor device through the input/output pad, and configured to control the semiconductor device,
wherein the semiconductor device includes:
a stack structure including gate electrodes and interlayer insulating layers alternately stacked in a vertical direction;
a vertical channel structure penetrating through the stack structure and including a data storage layer;
an insulating structure on the stack structure;
gate contact plugs penetrating through the insulating structure and extending downwardly and connected to contact regions of the gate electrodes; and
insulating spacers on side surfaces of the gate contact plugs,
wherein the insulating structure includes at least one intermediate insulating layer on the stack structure and a capping insulating layer on the at least one intermediate insulating layer,
wherein a material of the capping insulating layer is different from a material of the insulating spacers, and
wherein a first gate contact plug of the gate contact plugs includes a first plug portion in contact with a first insulating spacer of the insulating spacers, and a second plug portion in contact with the capping insulating layer.

20. The data storage system of claim 19, wherein the capping insulating layer includes an extension portion extending from a portion covering an upper surface of the at least one intermediate insulating layer to a portion between the side surfaces of the gate contact plugs and the at least one intermediate insulating layer.
